(19) United States
(12) Patent Application Publication
(10) Pub. No.: US 2023/0396036 A1
(43) Pub. Date: Dec. 7, 2023

(54) SEMICONDUCTOR LASER LIGHT EMITTING DEVICE

(71) Applicant: Nuvoton Technology Corporation Japan, Kyoto (JP)

(72) Inventors: Hiroki SHIROZONO, Toyama (JP); Masanori HIROKI, Shiga (JP); Shigeo HAYASHI, Kyoto (JP)

(21) Appl. No.: 18/453,033

(22) Filed: Aug. 21, 2023

Related U.S. Application Data
(63) Continuation of application No. PCT/JP2022/007030, filed on Feb. 21, 2022.

(30) Foreign Application Priority Data
Feb. 25, 2021 (JP) 2021-029280

(51) Int. Cl. H01S 5/02315; H01S 5/40; H01S 5/02255

(52) U.S. Cl. CPC H01S 5/02315; H01S 5/02255; H01S 5/4031

(57) ABSTRACT

A semiconductor laser light emitting device includes: a mounting substrate that is an example of a mounting base including a step; a submount disposed above a bottom face of the step; and a semiconductor laser disposed on the submount. A first lateral face of the step and a front face of the submount are in thermal contact with each other, the front face of the submount being a face of the submount on a light-emission direction side of the semiconductor laser.

### CROSS REFERENCE TO RELATED APPLICATIONS

This is a continuation application of PCT International Application No. PCT/JP2022/007030 filed on Feb. 21, 2022, designating the United States of America, which is based on and claims priority of Japanese Patent Application No. 2021-029280 filed on Feb. 25, 2021. The entire disclosures of the above-identified applications, including the specifications, drawings and claims are incorporated herein by reference in their entirety.

### FIELD

The present disclosure relates to a semiconductor laser light emitting device including a semiconductor laser.

### BACKGROUND

Semiconductor laser light emitting devices are used as light sources in products in a variety of fields such as projectors, in-vehicle headlamps, or laser processing equipment. A semiconductor laser light emitting device of this type includes, for example, a substrate that is a mounting base, a submount that is mounted on the substrate, and a semiconductor laser that is mounted on the submount (see Patent Literature (PTL) 1, for example).

### CITATION LIST

### Patent Literature

PTL 1: Japanese Unexamined Patent Application Publication No. 2015-228401

### SUMMARY

### Technical Problem

So far, there has been a demand for high power semiconductor laser light emitting devices. In recent years, however, there has been a demand for higher power semiconductor laser light emitting devices.

In order to achieve a higher power semiconductor laser light emitting device, it is conceivable that a current flowing through a semiconductor laser is increased or a plurality of semiconductor lasers are used.

However, when the current flowing through the semiconductor laser is increased or the plurality of semiconductor lasers are used, the amount of heat generated in the semiconductor laser increases to raise a temperature of the semiconductor laser, which leads to a reduction in output of laser light emitted from the semiconductor laser or a deterioration of the reliability of the semiconductor laser.

For this reason, when a higher power semiconductor laser light emitting device is achieved, efficiently conducting heat generated in a semiconductor laser to a mounting base is a problem. Moreover, for the semiconductor laser light emitting device, accurately mounting the semiconductor laser on the mounting base is also a problem.

The present disclosure has been conceived to solve such problems, and has an object to provide a semiconductor laser light emitting device that is capable of efficiently conducting heat generated in a semiconductor laser to a mounting base via a submount as well as enables the semiconductor laser to be accurately mounted on the mounting base.

### Solution to Problem

In order to achieve the above object, a semiconductor laser light emitting device according to one aspect of the present disclosure includes: a mounting base including a step; a submount disposed above a bottom face of the step; and a semiconductor laser disposed on the submount. A first lateral face of the step and a front face of the submount are in thermal contact with each other, the first lateral face being an inner lateral face of the step, the front face being a face of the submount on a light-emission direction side of the semiconductor laser.

### Advantageous Effects

According to the present disclosure, it is possible to efficiently conduct heat generated in a semiconductor laser to a mounting base via a submount and to accurately mount the semiconductor laser on the mounting base.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1A is a perspective view of a semiconductor laser light emitting device according to Embodiment 1.

FIG. 1B is a top view of the semiconductor laser light emitting device according to Embodiment 1.

FIG. 2A is a cross-sectional view of a portion of the semiconductor laser light emitting device according to Embodiment 1.

FIG. 2B is a top view of the portion of the semiconductor laser light emitting device according to Embodiment 1.

FIG. 2C is a perspective view of the portion of the semiconductor laser light emitting device according to Embodiment 1.

FIG. 3 is a cross-sectional view of a configuration of a semiconductor laser light emitting device according to Comparative Example 1 and heat dissipation paths.

FIG. 4 is a cross-sectional view of a configuration of the semiconductor laser light emitting device according to Embodiment 1 and heat dissipation paths.

FIG. 5A is a cross-sectional view of a portion of a semiconductor laser light emitting device according to Variation 1 of Embodiment 1.

FIG. 5B is a top view of the portion of the semiconductor laser light emitting device according to Variation 1 of Embodiment 1.

FIG. 5C is a perspective view of the portion of the semiconductor laser light emitting device according to Variation 1 of Embodiment 1.

FIG. 6A is a cross-sectional view of a portion of a semiconductor laser light emitting device according to Variation 2 of Embodiment 1.

FIG. 6B is a top view of the portion of the semiconductor laser light emitting device according to Variation 2 of Embodiment 1.

FIG. 6C is a perspective view of the portion of the semiconductor laser light emitting device according to Variation 2 of Embodiment 1.

FIG. 7 is a cross-sectional view of a portion of a semiconductor laser light emitting device according to Variation 3 of Embodiment 1.

FIG. 8 is a cross-sectional view of a portion of a semiconductor laser light emitting device according to Variation 4 of Embodiment 1.

FIG. 9A is a cross-sectional view of a portion of a semiconductor laser light emitting device according to Embodiment 2.

FIG. 9B is a top view of the portion of the semiconductor laser light emitting device according to Embodiment 2.

FIG. 9C is a perspective view of the portion of the semiconductor laser light emitting device according to Embodiment 2.

FIG. 10A is a cross-sectional view of a portion of a semiconductor laser light emitting device according to a variation of Embodiment 2.

FIG. 10B is a top view of the portion of the semiconductor laser light emitting device according to the variation of Embodiment 2.

FIG. 10C is a perspective view of the portion of the semiconductor laser light emitting device according to the variation of Embodiment 2.

FIG. 11A is a cross-sectional view of a portion of a semiconductor laser light emitting device according to Embodiment 3.

FIG. 11B is a top view of the portion of the semiconductor laser light emitting device according to Embodiment 3.

FIG. 11C is a perspective view of the portion of the semiconductor laser light emitting device according to Embodiment 3.

FIG. 12 is a cross-sectional view of a configuration of a semiconductor laser light emitting device according to Comparative Example 2.

FIG. 13 is a cross-sectional view of a configuration of the semiconductor laser light emitting device according to Embodiment 3.

FIG. 14 is a top view of a configuration of a semiconductor laser light emitting device according to Variation 1 of Embodiment 3.

FIG. 15 is a top view of a configuration of a semiconductor laser light emitting device according to Variation 2 of Embodiment 3.

FIG. 16A is a top view of a portion of a semiconductor laser light emitting device according to Embodiment 4.

FIG. 16B is a perspective view of the portion of the semiconductor laser light emitting device according to Embodiment 4.

FIG. 17A is a top view of a portion of a semiconductor laser light emitting device according to Variation 1 of Embodiment 4.

FIG. 17B is a perspective view of the portion of the semiconductor laser light emitting device according to Variation 1 of Embodiment 4.

FIG. 18A is a top view of a portion of a semiconductor laser light emitting device according to Variation 2 of Embodiment 4.

FIG. 18B is a perspective view of the portion of the semiconductor laser light emitting device according to Variation 2 of Embodiment 4.

FIG. 19 is an exploded perspective view of a semiconductor laser light emitting device according to another variation.

### DESCRIPTION OF EMBODIMENTS

Hereinafter, embodiments of the present disclosure are described with reference to the drawings. It should be noted that each of the embodiments described below shows one specific example of the present disclosure. Therefore, numerical values, shapes, materials, constituent elements, the arrangement and connection of the constituent elements, steps (processes), the order of steps, etc. shown in the following embodiments are mere examples, and are not intended to limit the scope of the present disclosure. Accordingly, among the constituent elements in the following embodiments, those not recited in any one of the independent claims indicating the broadest concept are described as optional constituent elements.

Moreover, the respective figures are schematic diagrams and are not necessarily precise illustrations. Therefore, the scales etc. in the respective figures are not necessarily uniform. In the respective figures, the same reference sign is assigned to substantially identical constituent elements, and overlapping descriptions thereof are omitted or simplified.

### Embodiment 1

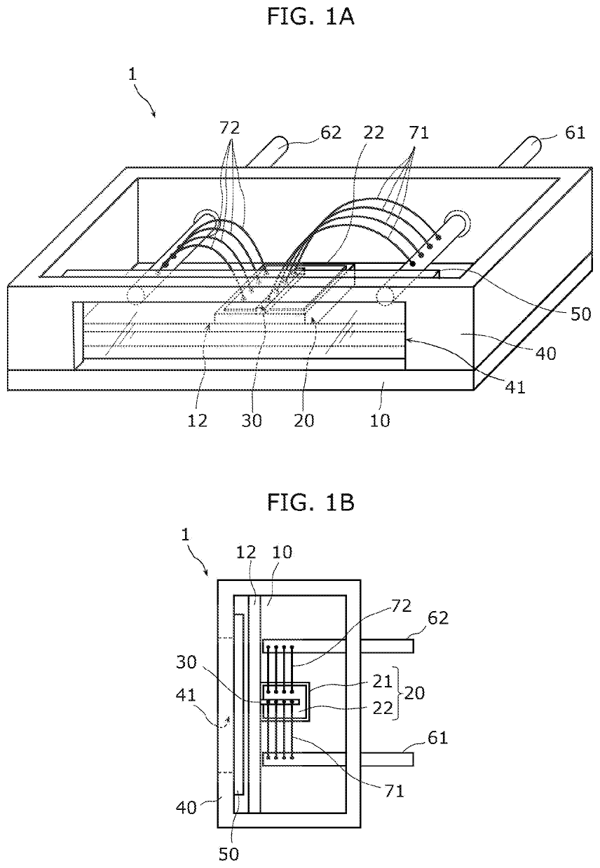

First, an entire configuration of semiconductor laser light emitting device 1 according to Embodiment 1 is described with reference to FIG. 1A and FIG. 1B. FIG. 1A is a perspective view of semiconductor laser light emitting device 1 according to Embodiment 1. FIG. 1B is a top view of semiconductor laser light emitting device 1 according to Embodiment 1. It should be noted that FIG. 1A and FIG. 1B each show a state in which a top cover of semiconductor laser light emitting device 1 is removed.

As shown in FIG. 1A and FIG. 1B, semiconductor laser light emitting device 1 includes mounting substrate 10, submount 20 disposed on mounting substrate 10, and semiconductor laser 30 disposed on submount 20.

In the present embodiment, semiconductor laser light emitting device 1 further includes frame 40, light-transmissive component 50, and a top cover (not shown in the figure). In semiconductor laser light emitting device 1, mounting substrate 10, frame 40, light-transmissive component 50, and the top cover constitute a case whose external shape is substantially a cuboid. The case contains submount 20 and semiconductor laser 30. The case may have an enclosed space. In other words, semiconductor laser 30 may be disposed in the enclosed space.

Frame 40 is disposed on mounting substrate 10 to surround submount 20 and semiconductor laser 30. Specifically, when an emission direction of semiconductor laser 30 is defined as a front, frame 40 is composed of lateral walls surrounding the lateral portions and rear portions of submount 20 and semiconductor laser 30, and is provided along the outer periphery of mounting substrate 10. In the present embodiment, a lateral wall of frame 40 is also provided on a side in front of submount 20 and semiconductor laser 30. It should be noted that although not shown in the figure, a plate-shaped top cover is disposed on a top edge of frame 40 to cover semiconductor laser 30. Although frame 40 and the top cover each include, for example, a metal material such as copper, the present disclosure is not limited to this example.

Opening portion 41 is formed in a portion of frame 40 in front of semiconductor laser 30. Light-transmissive component 50 is disposed to cover opening portion 41 of frame 40. Light emitted from semiconductor laser 30 passes through light-transmissive component 50 to the outside of semiconductor laser light emitting device 1. Although light-transmissive component 50 is, for example, a transparent plate such as a glass plate including borosilicate glass, the present disclosure is not limited to this example.

A pair of lead pins 61 and 62 are attached, as conductive electrode terminals for supplying power to semiconductor laser 30 from the outside, to portions of frame 40 behind semiconductor laser 30. Specifically, the pair of lead pins 61 and 62 are inserted into through holes formed in the rear portions of frame 40. It should be noted that when frame 40 includes a conductive material, the inner faces of the through holes in frame 40, into which the pair of lead pins 61 and 62 are inserted, are covered with an insulating component such as hermetic sealing glass.

The pair of lead pins 61 and 62 are electrically connected to a pair of electrodes of semiconductor laser 30. Specifically, lead pin 61 is connected to one of the electrodes of semiconductor laser 30 with gold wires 71. Moreover, lead pin 62 is connected to electrode 22 of submount 20 with gold wires 72 to which an other of the electrodes of semiconductor laser 30 is bonded. In the present embodiment, lead pin 61 is a cathode terminal, and lead pin 62 is an anode terminal. As an example, lead pins 61 and 62 include Fe—Ni alloy. It should be noted that although the number of gold wires 71 provided and the number of gold wires 72 provided each are plural, the present disclosure is not limited to this example. The number of gold wires 71 and the number of gold wires 72 may each be one.

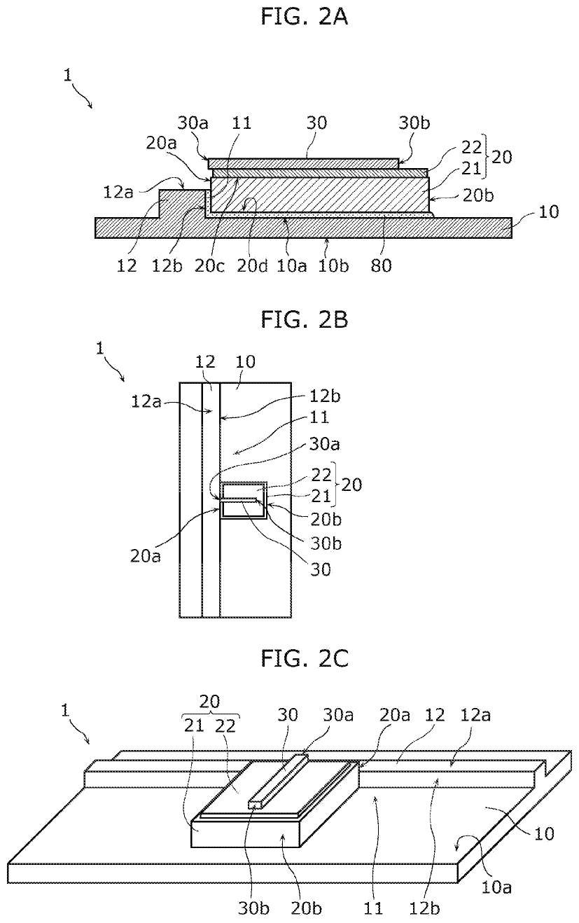

Next, a detailed structure of semiconductor laser light emitting device 1 according to the present embodiment is described with reference to FIG. 2A, FIG. 2B, and FIG. 2C. FIG. 2A, FIG. 2B, and FIG. 2C each are a diagram showing a portion of semiconductor laser light emitting device 1 shown in FIG. 1A and FIG. 1B, and are a cross-sectional view, a top view, and a perspective view of the portion of semiconductor laser light emitting device 1, respectively. It should be noted that FIG. 2B and FIG. 2C do not show bonding component 80.

Mounting substrate 10 is an example of a mounting base for mounting semiconductor laser 30 and submount 20. Specifically, submount 20 on which semiconductor laser 30 is mounted is mounted on mounting substrate 10.

As shown in FIG. 2A to FIG. 2C, mounting substrate 10 is in a tabular shape as a whole, and includes first principal surface 10a and second principal surface 10b that is on a side opposite to first principal surface 10a as shown in FIG. 2A. In the present embodiment, submount 20 is mounted on first principal surface 10a of mounting substrate 10. Although the shape of mounting substrate 10 in a top view is, for example, quadrilateral, the present disclosure is not limited to this example.

Moreover, a material of mounting substrate 10 is, for example, a metal material, a ceramic material, a glass material, or a resin material. In order to efficiently conduct heat generated in semiconductor laser 30 to mounting substrate 10 via submount 20, mounting substrate 10 may include a material having a high thermal conductivity such as a metal material. Examples of a metal material that has a high thermal conductivity and is practical as mounting substrate 10 include copper or aluminum. In the present embodiment, mounting substrate 10 is a copper substrate including copper.

As shown in FIG. 2A to FIG. 2C, mounting substrate 10 includes step 11. To put it differently, mounting substrate 10 is an example of a mounting base including step 11. In the present embodiment, mounting substrate 10 includes protruding portion 12, and protruding portion 12 forms step 11. Specifically, step 11 is formed by protruding portion 12 being provided on first principal surface 10a of mounting substrate 10. Accordingly, a top face of step 11 is top face 12a of protruding portion 12, an inner lateral face of step 11 that is a rising face of step 11 is lateral face 12b of protruding portion 12, and a bottom face of step 11 that is a sunken face of step 11 is first principal surface 10a of mounting substrate 10. Additionally, protruding portion 12 is provided opposite to submount 20, and lateral face 12b of protruding portion 12 (the inner lateral face of step 11) is opposite to front face 20a of submount 20.

In the present embodiment, protruding portion 12 is a bar-shaped cuboid. In other words, protruding portion 12 is a laid quadrilateral prism whose cross-sectional shape is quadrilateral. Accordingly, the shape of each of top face 12a of protruding portion 12 (the top face of step 11) and lateral face 12b of protruding portion 12 (the inner lateral face of step 11) is rectangular. Moreover, top face 12a of protruding portion 12 (the top face of step 11) and lateral face 12b of protruding portion 12 (the inner lateral face of step 11) are perpendicular to each other, and lateral face 12b of protruding portion 12 (the inner lateral face of step 11) and first principal surface of mounting substrate 10 (the bottom face of step 11) are perpendicular to each other. The term perpendicular in the Specification need not be strictly perpendicular, and includes a case of being substantially perpendicular in which a deviation from the perpendicularity is at most 5°.

Furthermore, lateral face 12b of protruding portion 12 (the inner lateral face of step 11) and front face 20a of submount 20 are parallel to each other. As shown in FIG. 2A, the cross-sectional shape of protruding portion 12 is quadrilateral; and when submount body 21 has a thickness of 200 μm, protruding portion 12 has a step height of 160 μm and a step width of 160 μm or a step height of 80 μm and a step width of 80 μm. However, the present disclosure is not limited to this example. The term parallel in the Specification need not be strictly parallel, and includes a case of being substantially parallel in which a deviation from the parallelism is at most 5°.

As shown in FIG. 2B and FIG. 2C, protruding portion 12 extends in a width direction of semiconductor laser 30. Accordingly, a longitudinal direction of protruding portion 12 is the width direction of semiconductor laser 30. Protruding portion 12 has a length greater than the width of submount 20. Specifically, when submount is viewed from the front, protruding portion 12 covers entire front face 20a of submount 20 in the width direction, and each of both ends of protruding portion 12 in the longitudinal direction is located outside of a corresponding one of both ends of front face 20a of submount 20 in the width direction.

It should be noted that although step 11 is formed by providing protruding portion 12 on mounting substrate 10 in the present embodiment, the present disclosure is not limited to this example. For example, step 11 may be formed by providing a recessed portion on mounting substrate 10. In this case, a top face (upper face) of step 11 is first principal surface 10a of mounting substrate 10, an inner lateral face of step 11 is an inner lateral face of the recessed portion, and a bottom face of step 11 is a bottom face of the recessed portion. Submount 20 is mounted not on first principal surface 10a of mounting substrate 10 but on the bottom face of the recessed portion.

As shown in FIG. 2A to FIG. 2C, submount 20 is disposed on mounting substrate 10. Specifically, submount 20 is disposed on the bottom face of step 11 of mounting substrate 10. In the present embodiment, since the bottom face of step 11 is first principal surface of mounting substrate 10, submount 20 is disposed on first principal surface 10a of mounting substrate 10. To put it differently, first principal surface 10a of mounting substrate 10 is a mounting face on which submount 20 is mounted.

Submount 20 is a base that supports semiconductor laser 30. Semiconductor laser 30 is disposed on submount 20. In other words, semiconductor laser 30 is located above submount 20. In addition, submount 20 is located above mounting substrate 10. Accordingly, submount 20 is located between mounting substrate 10 and semiconductor laser 30. As stated above, submount 20 and semiconductor laser 30 are stacked on mounting substrate 10 in stated order.

Submount 20 includes submount body 21 and electrode 22. Submount 20 also serves as a heat sink for dissipating heat generated in semiconductor laser 30. For this reason, submount body 21 may include either a conductive material or an insulating material, but submount body 21 may include a material having a high thermal conductivity. Submount body 21 may have a thermal conductivity of, for example, at least 150 W/(m·K). As an example, submount body 21 includes ceramic such as aluminum nitride (AlN) or polycrystalline silicon carbide (SiC), a metal material such as copper, or diamond such as monocrystalline diamond or polycrystalline diamond. In the present embodiment, submount body 21 is composed of AlN. It should be noted that although the shape of submount body 21 is, for example, a quadrilateral-plate-shaped cuboid, the present disclosure is not limited to this example.

Submount 20 includes front face 20a that is a face on a light-emission direction side of semiconductor laser 30, and rear face 20b that is a face on a side opposite to the light-emission direction side of semiconductor laser 30. Front face 20a of submount 20 is a front end face of submount body 21, and rear face 20b of submount 20 is a rear end face of submount body 21. Front face 20a of submount 20 is a face opposite to step 11 formed on mounting substrate 10. Specifically, front face 20a of submount 20 is opposite to protruding portion 12 provided on mounting substrate 10. It should be noted that since submount body 21 is in a quadrilateral plate shape in the present embodiment, the shapes of front face 20a and rear face 20b of submount 20 are rectangular. In addition, in submount 20, front face 20a and rear face 20b are substantially parallel to each other.

Electrode 22 (a submount electrode) is disposed on a top face of submount body 21 (a face on a semiconductor laser 30 side). Electrode 22 includes a conductive material such as a metal material. In the present embodiment, electrode 22 is a copper electrode including copper. It should be noted that electrode 22 may include a single conductive film or a plurality of conductive films.

As shown in FIG. 2A, submount 20 includes top face 20c that is a face on the semiconductor laser 30 side, and bottom face 20d that is a face on a mounting substrate 10 side. In the present embodiment, top face 20c of submount 20 is a top face of electrode 22, and bottom face 20d of submount 20 is a bottom face of submount body 21. In submount 20, top face 20c and bottom face 20d are substantially parallel to each other.

Mounting substrate 10 and submount 20 are bonded with bonding component 80. In other words, bonding component 80 is inserted between mounting substrate 10 and submount 20. Specifically, bonding component 80 is interposed between first principal surface 10a of mounting substrate 10 and bottom face 20d of submount 20. In the present embodiment, bonding component 80 is further interposed between lateral face 12b of protruding portion 12, which is the inner lateral face of step 11 of mounting substrate 10, and front face 20a of submount 20. Although bonding component 80 is, for example, an Au paste, the present disclosure is not limited to this example.

Moreover, although not shown in the figure, semiconductor laser 30 and submount 20 are also bonded with a bonding component. Specifically, the bonding component is interposed between semiconductor laser 30 and top face 20c of submount 20. The bonding component that bonds semiconductor 30 and submount 20 can be, for example, an AuSn solder.

When mounting substrate 10 and submount 20 are bonded, for example, by applying an Au paste as bonding component 80 to mounting substrate 10 and disposing submount 20 to which semiconductor laser 30 is bonded on the Au paste after semiconductor laser 30 is bonded to submount 20 with an AuSn solder, it is possible to bond submount 20 to mounting substrate 10.

Semiconductor laser 30 is a semiconductor laser element (a laser chip) that emits laser light. In the present embodiment, semiconductor laser 30 is a nitride-based semiconductor laser element including a nitride-based semiconductor material. As an example, semiconductor laser 30 is a GaN-based semiconductor laser element that emits blue laser light.

Semiconductor laser 30 includes front end face 30a that is an end face on a side toward which laser light is emitted, and rear end face 30b that is an end face on a rear side opposite to front end face 30a. In addition, semiconductor laser 30 includes an optical waveguide provided between front end face 30a and rear end face 30b.

Semiconductor laser 30 is in an elongated shape with a resonator length direction as a longitudinal direction. As an example, semiconductor laser 30 has a length of 1.2 mm in the resonator length direction. However, the present disclosure is not limited to this example.

Semiconductor laser 30 is mounted on top face 20c of submount 20. Specifically, semiconductor laser 30 is mounted on electrode 22 of submount 20. In the present embodiment, semiconductor laser 30 is mounted on submount 20 by junction-down mounting. It should be noted that a mounting mode of semiconductor laser 30 is not limited to this example, and semiconductor laser 30 may be mounted on submount 20 by junction-up mounting.

Furthermore, semiconductor laser 30 is mounted to cause front end face 30a to protrude from front face 20a of submount 20. In other words, semiconductor laser 30 protrudes from front face 20a of submount 20, and front end face 30a of semiconductor laser 30 is located on the light-emission direction side of semiconductor laser 30 from front face 20a of submount 20. Although the amount of protrusion of semiconductor laser 30 (a distance from front face 20a of submount 20 to front end face 30a of semiconductor laser 30) is, for example, between 5 μm and 20 μm inclusive, the present disclosure is not limited to this example. In the present embodiment, the amount of protrusion of semiconductor laser 30 is 10 μm.

Although semiconductor laser 30 protrudes from front face 20a of submount 20 as stated above, semiconductor laser 30 does not protrude to step 11 of mounting substrate 10. To put it differently, semiconductor laser 30 does not protrude to protruding portion 12 provided on mounting substrate 10, and a front end portion of semiconductor laser 30 does not overlap protruding portion 12 in a top view. Front end face 30a of semiconductor laser 30 is located between front face 20a of submount 20 and lateral face 12b of protruding portion 12. It should be noted that semiconductor laser may protrude to step 11 of mounting substrate 10. That is to say, the front end portion of semiconductor laser 30 may overlap protruding portion 12 provided on mounting substrate 10 in the top view.

In semiconductor laser light emitting device 1 according to the present embodiment, lateral face 12b of protruding portion 12, which is the inner lateral face of step 11 formed on mounting substrate 10, and front face 20a of submount 20, are in thermal contact with each other. In this case, lateral face 12b of protruding portion 12, which is the inner lateral face of step 11, and front face 20a of submount may be physically close to or in contact with each other.

In the present embodiment, lateral face 12b of protruding portion 12 (the inner lateral face of step 11) and front face 20a of submount 20 are close to each other but not in direct contact with each other. Specifically, lateral face 12b of protruding portion 12 (the inner lateral face of step 11) and front face 20a of submount 20 are connected with only thin bonding component 80 being interposed therebetween.

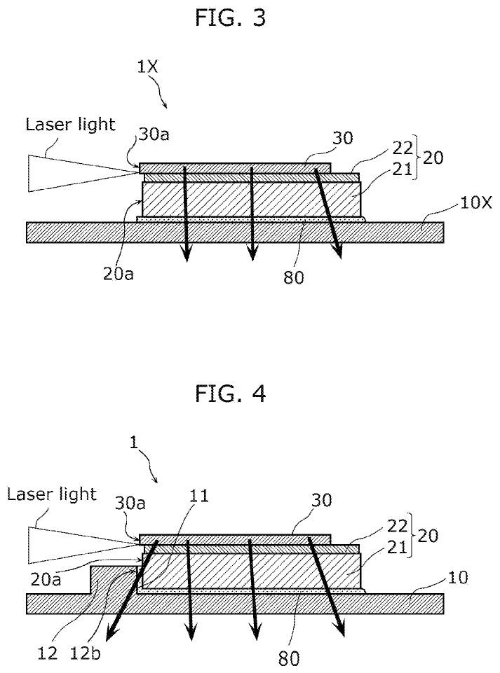

Here, advantageous effects achieved by semiconductor laser light emitting device 1 according to the present embodiment are described with reference to FIG. 3 and FIG. 4, compared to semiconductor laser light emitting device 1X according to Comparative Example 1. FIG. 3 is a cross-sectional view of a configuration of semiconductor laser light emitting device 1X according to Comparative Example 1 and heat dissipation paths. FIG. 4 is a cross-sectional view of a configuration of semiconductor laser light emitting device 1 according to the present embodiment and heat dissipation paths. It should be noted that arrows indicate heat dissipation paths for heat generated in semiconductor laser 30 in FIG. 3 and FIG. 4.

As shown in FIG. 3, semiconductor laser light emitting device 1X according to Comparative Example 1 differs from semiconductor laser light emitting device 1 according to the present embodiment in having a structure in which step 11 is not formed on mounting substrate 10X. Specifically, in semiconductor laser light emitting device 1X according to Comparative Example 1, protruding portion 12 is not provided on mounting substrate 10X.

In semiconductor laser light emitting device 1X according to Comparative Example 1 thus configured, when heat is generated in semiconductor laser 30 due to emission of laser light from semiconductor laser 30, the heat generated in semiconductor laser 30 is conducted to mounting substrate 10X via the heat dissipation paths shown in FIG. 3.

In semiconductor laser light emitting device 1X according to Comparative Example 1, however, when a current flowing through semiconductor laser 30 is increased to achieve high power, the amount of heat generated in semiconductor laser 30 increases to raise a temperature of semiconductor laser 30, which leads to a reduction in output of laser light emitted from semiconductor laser 30 or a deterioration of the reliability of semiconductor laser 30.

In particular, since semiconductor laser light emitting device 1X according to Comparative Example 1 has a structure in which semiconductor laser 30 protrudes from front face 20a of submount 20, heat generated in the vicinity of front end face 30a of semiconductor laser 30 is not easily conducted to mounting substrate 10, compared to other portions. For this reason, in semiconductor laser light emitting device 1X according to Comparative Example 1, a temperature of semiconductor laser 30 on a front face 20a side significantly rises.

In contrast, as shown in FIG. 4, in semiconductor laser light emitting device 1 according to the present embodiment, step 11 is formed on mounting substrate 10, and lateral face 12b of protruding portion 12, which is the inner lateral face of step 11, and front face of submount 20, are in thermal contact with each other.

In semiconductor laser light emitting device 1 thus configured, heat generated in semiconductor laser 30 is conducted to mounting substrate 10 via the heat dissipation paths shown in FIG. 4. In other words, semiconductor laser light emitting device 1 according to the present embodiment differs from semiconductor laser light emitting device 1X according to Comparative Example 1 in that a heat dissipation path through step 11 (protruding portion 12) located on the light-emission direction side of semiconductor laser 30 is added. Heat generated in the vicinity of front end face 30a of semiconductor laser 30 is conducted, via the added heat dissipation path, to the vicinity of front face 20a of submount 20, and conducted from front face 20a of submount 20 to the inner lateral face of step 11 (lateral face 12b of protruding portion 12) and then to mounting substrate 10. To put it differently, semiconductor laser light emitting device 1 according to the present embodiment makes it possible to efficiently conduct the heat generated in semiconductor laser 30 from front face of submount 20 to mounting substrate 10.

Accordingly, even when front end face 30a of semiconductor laser 30 protrudes from front face 20a of submount 20, it is possible to efficiently conduct the heat generated in the vicinity of front end face 30a of semiconductor laser 30 to mounting substrate 10. Additionally, since it is possible to efficiently conduct the heat generated in the vicinity of front end face 30a of semiconductor laser to mounting substrate 10 even when semiconductor laser 30 does not protrude from front face 20a of submount 20, it is possible to reduce a temperature in the vicinity of front end face 30a of semiconductor laser 30.

As stated above, semiconductor laser light emitting device 1 according to the present embodiment includes: mounting substrate that is a mounting base including step 11; submount 20 that is disposed above the bottom face of step 11; and semiconductor laser that is disposed on submount 20. The first lateral face of step 11 (lateral face 12b of protruding portion 12 in the present embodiment) and front face 20a of submount 20 are in thermal contact with each other, the first lateral face being an inner lateral face of step 11. In other words, semiconductor laser light emitting device 1 according to the present embodiment uses step 11 (protruding portion 12) as a heat dissipation path, and the inner lateral face of step 11 (lateral face 12b of protruding portion 12) for heat dissipation and front face of submount 20 are in thermal contact with each other.

This configuration makes it possible to efficiently conduct the heat generated in semiconductor laser 30 to mounting substrate 10 via submount 20. Accordingly, even when a current flowing through semiconductor laser 30 is increased to achieve high power, it is possible to prevent the output of laser light emitted from semiconductor laser 30 from being reduced or the reliability of semiconductor laser 30 from being deteriorated.

Moreover, in semiconductor laser light emitting device 1 according to the present embodiment, the inner lateral face of step 11 (lateral face 12b of protruding portion 12) and front face 20a of submount 20 are opposite to each other.

Accordingly, it is possible to use step 11 formed on mounting substrate 10 as a reference for aligning submount 20 and semiconductor laser 30 with mounting substrate 10. For example, when submount 20 on which semiconductor laser 30 is disposed is mounted on mounting substrate 10, after submount 20 is pressed onto mounting substrate 10 with a bonding component prior to curing being interposed therebetween, submount 20 and mounting substrate are cured and bonded by, for example, heating in a furnace. In contrast, in the present embodiment, it is possible to accurately mount submount 20, on which semiconductor laser 30 is disposed, at a predetermined position of mounting substrate 10 by pressing submount 20, on which semiconductor laser 30 is disposed, toward the inner lateral face of step 11 (lateral face 12b of protruding portion 12). Stated differently, step 11 formed on mounting substrate 10 makes it possible to determine the positions of submount 20 and semiconductor laser 30 in a substrate horizontal direction. Specifically, bonding component 80 prior to curing is disposed on mounting substrate 10, and the position of submount 20 is determined by also pressing submount 20 in a direction of step 11 in a state in which submount 20 is pressed onto bonding component 80. Furthermore, a bonded state is achieved by curing bonding component 80 in that state. Accordingly, it is possible to improve the accuracy of mounting semiconductor laser 30 on mounting substrate 10. Consequently, it is possible to accurately mount semiconductor laser 30 on mounting substrate 10 with submount 20 being interposed therebetween.

As stated above, in semiconductor laser light emitting device 1 according to the present embodiment, it is possible to use step 11 (protruding portion 12) formed on mounting substrate 10 not only for heat dissipation but also for alignment.

According to semiconductor laser light emitting device 1 according to the present embodiment, it is possible not only to efficiently conduct the heat generated in semiconductor laser 30 to mounting substrate 10 via submount 20 but also to accurately mount semiconductor laser 30 on mounting substrate 10. In other words, it is possible to achieve both the improvement of heat dissipation performance and the improvement of mounting accuracy of semiconductor laser 30.

Moreover, in semiconductor laser light emitting device 1 according to the present embodiment, a position of a top edge of the inner lateral face of step 11 (lateral face 12b of protruding portion 12) of mounting substrate 10 is at the same height or lower than a position of a top edge of front face 20a of submount 20. To put it differently, the height of a portion of top face 12a of protruding portion 12 on a submount 20 side is less than or equal to the height of submount 20, top face 12a being a top face of step 11.

This configuration makes it possible to ensure an optical path of light emitted from semiconductor laser 30. In other words, although light (laser light) emitted from semiconductor laser 30 spreads in a vertical direction, such a configuration makes it possible to prevent the light emitted from semiconductor laser 30 from being blocked by step 11 (protruding portion 12). As stated above, semiconductor laser light emitting device 1 according to the present embodiment makes it possible to improve the heat dissipation performance of semiconductor laser 30 while ensuring the optical path of the light emitted from semiconductor laser 30.

In this case, a distance from bottom face 20d of submount 20 to the top edge of the inner lateral face of step 11 (lateral face 12b of protruding portion 12) may be at least 40% and at most 100% of a distance from bottom face 20d of submount body 21 to top face 20c of submount body 21. Stated differently, a distance from bottom face 20d of submount body 21 to the topmost position of the top face of step 11 (top face 12a of protruding portion 12) may be at least 40% and at most 100% of the thickness of submount body 21. In the case where the distance exceeds 100% of the thickness of submount body 21, there is a possibility that when submount body 21 is pressed to protruding portion 12, bonding component 80 interposed therebetween rises to block the optical path. On the other hand, when the distance is less than 40% of the thickness of submount body 21, the effect of improving heat dissipation becomes less remarkable.

This configuration makes it possible to further prevent the light emitted from semiconductor laser 30 from being blocked by step 11 (protruding portion 12).

Furthermore, in semiconductor laser light emitting device 1 according to the present embodiment, the inner lateral face of step 11 of mounting substrate 10 and the bottom face of step 11 are perpendicular to each other. In the present embodiment, lateral face 12b of protruding portion 12, which is the inner lateral face of step 11, and first principal surface 10a of mounting substrate 10, which is the bottom face of step 11, are perpendicular to each other.

Since this configuration makes it possible to bond the entire inner lateral face of step 11 (lateral face 12b of protruding portion 12) and the entire bottom face of step 11 (first principal surface 10a of mounting substrate 10), it is possible to further improve the heat dissipation performance of semiconductor laser 30. Moreover, when lateral face 12b of protruding portion 12 and first principal surface of mounting substrate 10 are perpendicular to each other, in the step of pressing submount 20 when submount 20 is bonded to mounting substrate 10 toward the inner lateral face of step 11, it is possible to prevent submount 20 from being displaced in up and down directions due to the inclination of a contact face of step 11 or from rotating vertically. It should be noted that, for example, when a deviation from the perpendicularity is 5°, force of pressing submount to the inner lateral face of step 11 in the horizontal direction is converted into upward force equivalent to approximately tan 5°, that is, approximately 9% due to the inclination of an end face of submount 20. However, since the upward force is weaker than the force of pressing at the time of mounting submount 20, the upward force does not result in the remarkable rise of one side of submount 20. In other words, such a little deviation from the perpendicularity does not result in a decrease in the accuracy of mounting submount 20.

Moreover, in semiconductor laser light emitting device 1 according to the present embodiment, the inner lateral face of step 11 (lateral face 12b of protruding portion 12) of mounting substrate and front face 20a of submount 20 are parallel to each other.

Since this configuration makes it possible to bond the entire inner lateral face of step 11 (lateral face 12b of protruding portion 12) and entire front face 20a of submount 20, it is possible to further improve the heat dissipation performance of semiconductor laser 30. In particular, it is possible to effectively dissipate the heat generated in the vicinity of front end face 30a of semiconductor laser 30. It should be noted that in the case where there is, for example, an angle difference of 5°, when a portion at which lateral face 12b of protruding portion 12, which is the inner lateral face of step 11, and front face of submount 20, are opposite to each other has a length of 160 μm, compared to a side on which step 11 and submount 20 are in contact with each other, a gap between step 11 and submount 20 at the opposite end is 14 μm. However, such a little gap has no significant impact on effect on dissipation.

### Variation 1 of Embodiment 1

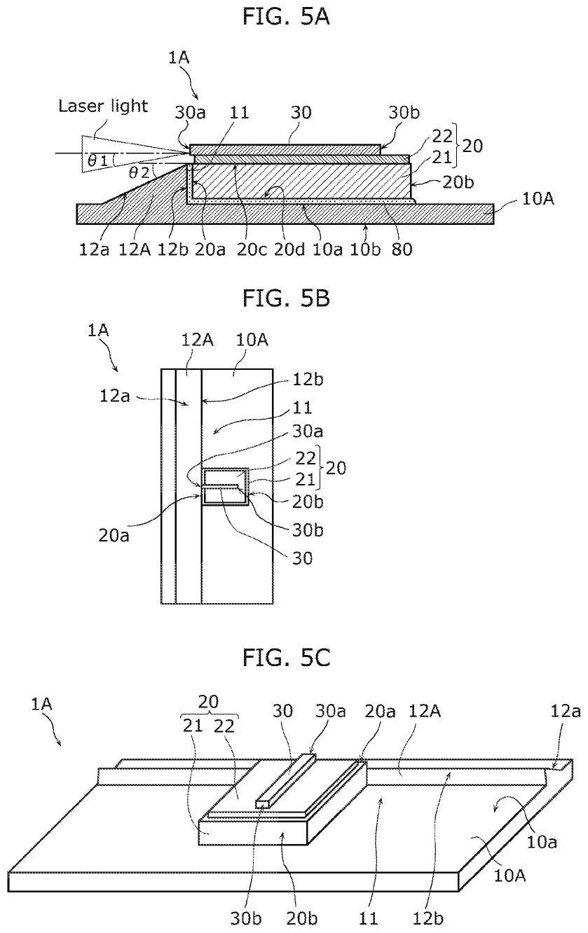

Next, Variation 1 of Embodiment 1 is described with reference to FIG. 5A, FIG. 5B, and FIG. 5C. FIG. 5A, FIG. 5B, and FIG. 5C are diagrams showing a portion of semiconductor laser light emitting device 1A according to Variation 1 of Embodiment 1, and are a cross-sectional view, a top view, and a perspective view of the portion of semiconductor laser light emitting device 1A, respectively. It should be noted that FIG. 5A, FIG. 5B, and FIG. 5C correspond to FIG. 2A, FIG. 2B, and FIG. 2C that show the portion of semiconductor laser light emitting device 1 according to above-described Embodiment 1, respectively.

As shown in FIG. 5A to FIG. 5C, semiconductor laser light emitting device 1A according to the present variation differs from semiconductor laser light emitting device 1 according to above-described Embodiment 1 in the shape of step 11. Specifically, in semiconductor laser light emitting device 1 according to above-described Embodiment 1, step 11 is formed by providing protruding portion 12, which is a cuboid (a quadrilateral prism), on mounting substrate 10. In contrast, in semiconductor laser light emitting device 1A according to the present variation, step 11 is formed by providing protruding portion 12A that is a laid triangular prism on mounting substrate 10A.

For this reason, in the present variation, top face 12a of protruding portion 12A that is the top face of step 11 becomes lower with distance from submount 20. Specifically, top face 12a of protruding portion 12A is a planar inclined face. In the present variation, protruding portion 12A is a triangular prism whose cross-sectional shape is a right-angled triangle. Specifically, protruding portion 12A is provided to cause a right-angled portion of the right-angled triangle to be located on the submount 20 side.

In this case, as shown in FIG. 5A, θ1<θ2 may be satisfied, where half of a vertical beam spread angle of light emitted from semiconductor laser 30 is denoted by θ1, and an angle formed by top face 12a, which is the top face of step 11 of mounting substrate 10A, and the top face of submount body 21 of submount 20 (i.e., an inclination angle of protruding portion 12A) is denoted by θ2. It should be noted that, in the present variation, since the top face of submount body 21 is parallel to a bottom face of semiconductor laser inclination angle θ2 of protruding portion 12A is an angle formed by the top face of step 11 (top face 12a of protruding portion 12A) and the bottom face of semiconductor laser 30.

Inclination angle θ2 of protruding portion 12A may be greater than 0° and at most 80°, at most 60° preferably, and at most 45° more preferably. Although the lower limit of inclination angle θ2 is not particularly limited, inclination angle θ2 may be at least 30°. Most preferable inclination angle θ2 is 45°. In the present variation, half angle θ1 of the vertical beam spread angle of the light emitted from semiconductor laser 30 is 23°, and inclination angle θ2 is 45°.

Moreover, although the cross-sectional triangle shape of protruding portion 12A is not particularly limited, when submount body 21 has a thickness of 200 μm, as an example, the cross-sectional shape of protruding portion 12A is a rectangular equilateral triangle (inclination angle θ2=45°) having a step height of 200 μm and a step width (bottom face) of 200 μm or a right-angled triangle (inclination angle θ2=30°) having a step height of 200 μm and a step width of 346 μm.

It should be noted that semiconductor laser light emitting device 1A according to the present variation has the same configuration as semiconductor laser light emitting device 1 according to above-described Embodiment 1, except that step 11 is formed by protruding portion 12A that is the triangular prism.

Accordingly, in the present variation, lateral face 12b of protruding portion 12A, which is the inner lateral face of step 11, and front face 20a of submount 20, are also in thermal contact with each other. In addition, in the present variation, lateral face 12b of protruding portion 12A, which is the inner lateral face of step 11, and front face 20a of submount 20, are also opposite to each other.

As with semiconductor laser light emitting device 1 according to above-described Embodiment 1, with regard to semiconductor laser light emitting device 1A according to the present variation, this configuration makes it possible not only to efficiently conduct the heat generated in semiconductor laser 30 to mounting substrate 10A via submount 20 but also to accurately mount semiconductor laser 30 on mounting substrate 10A.

Furthermore, in the present variation, top face 12a of protruding portion 12A, which is the top face of step 11, becomes lower with distance from submount 20.

Since the light emitted from semiconductor laser 30 spreads in the vertical direction with distance from submount 20, this configuration makes it possible to prevent the light emitted from semiconductor laser 30 from being blocked by step 11 (protruding portion 12A). As stated above, semiconductor laser light emitting device 1A according to the present variation makes it possible to improve the heat dissipation performance of semiconductor laser 30 while ensuring the optical path of the light emitted from semiconductor laser 30.

In this case, an angle formed by the top face of step 11 (top face 12a of protruding portion 12A) and top face 20c of submount 20 may be at most 45°. Since general heat conduction takes place in a direction within 45° relative to a main heat conduction direction (downward in the case of the present application), the heat dissipation is limited when the above angle is greater than 45°.

This configuration makes it possible to further prevent the light emitted from semiconductor laser 30 from being blocked by step 11 (protruding portion 12A) while maintaining the heat dissipation performance of semiconductor laser 30 using step 11 (protruding portion 12A).

Moreover, angle θ2 formed by the top face of step 11 (top face 12a of protruding portion 12A) and top face 20c of submount 20 may be less than or equal to θ1 that is half of a beam spread angle in a vertical direction of light emitted from semiconductor laser 30.

This configuration makes it possible to certainly prevent the light emitted from semiconductor laser 30 from being blocked by step 11 (protruding portion 12A).

It should be noted that although top face 12a of protruding portion 12A is a planar inclined face in the present variation, the present disclosure is not limited to this example as long as top face 12a of protruding portion 12A becomes lower with distance from submount 20. For example, top face 12a of protruding portion 12A may be configured to become lower in a stepwise manner.

### Variation 2 of Embodiment 1

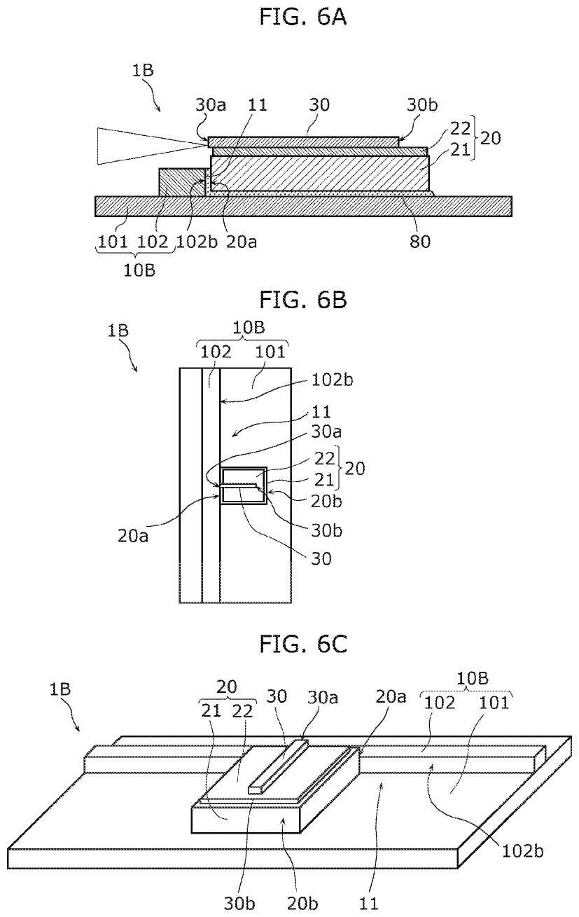

Next, Variation 2 of Embodiment 1 is described with reference to FIG. 6A, FIG. 6B, and FIG. 6C. FIG. 6A, FIG. 6B, and FIG. 6C are diagrams showing a portion of semiconductor laser light emitting device 1B according to Variation 2 of Embodiment 1, and are a cross-sectional view, a top view, and a perspective view of the portion of semiconductor laser light emitting device 1B, respectively. It should be noted that FIG. 6A, FIG. 6B, and FIG. 6C correspond to FIG. 2A, FIG. 2B, and FIG. 2C that show the portion of semiconductor laser light emitting device 1 according to above-described Embodiment 1, respectively.

As shown in FIG. 6A to FIG. 6C, semiconductor laser light emitting device 1B according to the present variation differs from semiconductor laser light emitting device 1 according to above-described Embodiment 1 in a configuration of mounting substrate 10B. Specifically, in semiconductor laser light emitting device 1 according to above-described Embodiment 1, step 11 is formed by providing protruding portion 12 on mounting substrate 10. In contrast, in semiconductor laser light emitting device 1B according to the present variation, mounting substrate 10B includes first component 101 and second component 102, and step 11 is formed by disposing second component 102 on first component 101.

First component 101 is a base substrate in mounting substrate 10B. Moreover, second component 102 is an additional component additionally disposed on first component 101. In the present variation, first component 101 is a quadrilateral-plate-shaped substrate having a certain thickness, and second component 102 is a bar-shaped cuboid (a quadrilateral prism). Second component 102 can have the same shape as protruding portion 12 in above-described Embodiment 1.

First component 101 and second component 102 include different materials. The materials of first component 101 and second component 102 can be the same as the material of mounting substrate 10 in above-described Embodiment 1. As an example, first component 101 is a copper substrate including copper. Although second component 102 may include a material having a thermal conductivity higher than a thermal conductivity of the material of first component 101, the present disclosure is not limited to this example.

It should be noted that semiconductor laser light emitting device 1B according to the present variation has the same configuration as semiconductor laser light emitting 1 according to above-described Embodiment 1, except that mounting substrate 10B includes first component 101 and second component 102.

Accordingly, in the present variation, lateral face 102b of second component 102 that is an inner lateral face of step 11, and front face 20a of submount 20, are also in thermal contact with each other. In addition, in the present variation, lateral face 102b of second component 102, which is the inner lateral face of step 11, and front face 20a of submount 20, are also opposite to each other.

As with semiconductor laser light emitting device 1 according to above-described Embodiment 1, with regard to semiconductor laser light emitting device 1B according to the present variation, this configuration makes it possible not only to efficiently conduct the heat generated in semiconductor laser 30 to mounting substrate 10B via submount 20 but also to accurately mount semiconductor laser 30 on mounting substrate 10B.

Additionally, in semiconductor laser light emitting device 1B according to the present variation, mounting substrate 10B, which is an example of the mounting base, includes first component 101 and second component 102 that differ in material, and step 11 is formed by disposing second component 102 on first component 101.

Since this configuration makes it possible to select a desired material for second component 102, it is possible to cause the thermal conductivity of second component 102 to be higher than the thermal conductivity of submount 20. This configuration makes it possible to efficiently conduct the heat generated in semiconductor laser 30 to mounting substrate 10B, compared to a configuration in which, for example, the lateral face shape of submount 20 is flared out at the bottom, and heat generated in the vicinity of front end face 30a of semiconductor laser 30 is conducted forward of front end face 30a of semiconductor laser 30 in submount 20 through similar thermal paths.

In this case, the thermal conductivity of second component 102 may be higher than or equal to the thermal conductivity of submount 20. In the present variation, since nitride aluminum having a thermal conductivity of approximately 150 [W/(m/K)] is used as the material of submount 20, second component 102 has a thermal conductivity of at least 150 [W/(m/K)].

This configuration makes it possible to more efficiently conduct the heat generated in the vicinity of front end face 30a of semiconductor laser 30 and conducted to submount 20 to second component 102 and first component 101. Accordingly, it is possible to further improve the heat dissipation performance of semiconductor laser 30.

It should be noted that although the shape of second component 102 of mounting substrate 10B is a quadrilateral prism in the present variation as with protruding portion 12 in above-described Embodiment 1, the present disclosure is not limited to this example. For example, the shape of second component 102 may be a triangular prism as with protruding portion 12A in Variation 1 of above-described Embodiment 1, or may be any shape other than the triangular prism.

In addition, although first component 101 and second component 102, which constitute mounting substrate 10B, differ in material, the present disclosure is not limited to this example. In other words, first component 101 and second component 102 may include the same material.

### Variation 3 of Embodiment 1

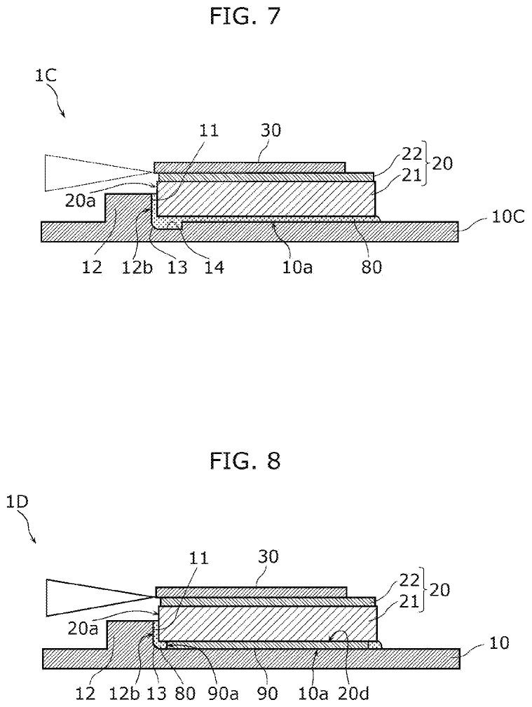

Next, Variation 3 of Embodiment 1 is described with reference to FIG. 7. FIG. 7 is a cross-sectional view of a portion of semiconductor laser light emitting device 1C according to Variation 3 of Embodiment 1. It should be noted that FIG. 7 corresponds to FIG. 2A that shows the portion of semiconductor laser light emitting device 1 according to above-described Embodiment 1.

When step 11 is formed on mounting substrate 10 by cutting using a drill or laser or by press working in above-described Embodiment 1, a step radius (step R) that is a corner radius (corner R) may be formed in a base portion of step 11 as a result of a base portion of the inner lateral face of step 11 being curved. To put it differently, the inner lateral face and bottom face of step 11 do not form a right angle, and curved portion 13 that curves in a cross-sectional arc-like shape may be formed in the base portion of step 11 as a result of a corner of the base portion of step 11 being rounded as shown in FIG. 7. For example, when step 11 is formed by cutting using a drill, a step radius having a height of approximately 23 μm is formed as curved portion 13; when step 11 is formed by cutting using laser, a step radius having a height of approximately 10 μm is formed as curved portion 13; and when step 11 is formed by press working, a step radius having a height of 30 μm is formed as curved portion 13.

As stated above, when curved portion 13 (the step radius) is formed in the base portion of step 11, there is a possibility that when submount 20 is mounted on mounting substrate 10C while determining the position of submount 20 using step 11, a portion of front face 20a of submount 20 runs onto curved portion 13, and submount 20 is inclined. In this case, there is a possibility that semiconductor laser 30 mounted on submount 20 is also inclined, and semiconductor laser 30 is not mounted on mounting substrate 10C in a correct orientation.

In view of this, as shown in FIG. 7, in semiconductor laser light emitting device 1C according to the present variation, in order that curved portion 13 (the step radius) may be formed in the base portion of the inner lateral face of step 11, groove 14 that is dug into mounting substrate 10C is provided along the inner lateral face of step 11 (lateral face 12b of protruding portion 12) of mounting substrate 10C. In other words, in the present variation, the bottom face of step 11 is the bottom face of groove 14, and the bottom face of groove 14 is located lower than first principal surface 10a (a mounting face on which submount 20 is mounted) of mounting substrate 10C in mounting substrate 10C.

Moreover, groove 14 is provided in the longitudinal direction of protruding portion 12. In this case, although the length of groove 14 in the longitudinal direction is equal to the length of protruding portion 12 in the longitudinal direction in the present variation, the length of groove 14 in the longitudinal direction may be greater than the length of protruding portion 12 in the longitudinal direction.

Furthermore, groove 14 may have a depth greater than or equal to the height of curved portion 13 (the step radius). Stated differently, a distance from first principal surface 10a of mounting substrate 10C to the bottom face of groove 14 may be greater than or equal to the height of curved portion 13 (the step radius). In consideration of the above-described cutting or press working etc., groove 14 may have a depth of at least 10 μm and preferably at least 30 μm. In the present variation, groove 14 has a depth of 50 μm.

It should be noted that semiconductor laser light emitting device 1C according to the present variation has the same configuration as semiconductor laser light emitting device 1 according to above-described Embodiment 1, except that groove 14 and curved portion 13 are provided on mounting substrate 10C.

Accordingly, in the present variation, lateral face 12b of protruding portion 12, which is the inner lateral face of step 11, and front face 20a of submount 20, are also in thermal contact with each other. In addition, in the present variation, lateral face 12b of protruding portion 12, which is the inner lateral face of step 11, and front face 20a of submount 20, are also opposite to each other.

As with semiconductor laser light emitting device 1 according to above-described Embodiment 1, with regard to semiconductor laser light emitting device 1C according to the present variation, this configuration makes it possible not only to efficiently conduct the heat generated in semiconductor laser 30 to mounting substrate 10C via submount 20 but also to accurately mount semiconductor laser 30 on mounting substrate 10C.

Moreover, in present variation, groove 14 that is dug into mounting substrate 10C and has a depth greater than or equal to the height of curved portion 13 (the step radius) is provided along the inner lateral face of step 11 (lateral face 12b of protruding portion 12).

Even when submount 20 is mounted on mounting substrate 10C using step 11 while determining the position of submount 20 in the case where curved portion 13 (the step radius) is provided in the base portion of the inner lateral face of step 11, this configuration makes it possible to prevent submount 20 from being inclined as a result of the portion of front face 20a of submount 20 running onto curved portion 13. In other words, it is possible to use groove 14 as a relief groove for preventing submount 20 from being inclined. Accordingly, it is possible to mount submount 20 and semiconductor laser 30 mounted on submount 20 on mounting substrate 10C in a correct orientation.

It should be noted that although groove 14 is filled with bonding component 80 in the present variation, the present disclosure is not limited to this example. In this regard, however, it is possible to improve the heat dissipation performance of semiconductor laser 30 more when groove 14 is filled with bonding component 80. To put it differently, by groove 14 being filled with bonding component 80, it is possible to efficiently conduct the heat generated in semiconductor laser 30 from submount 20 to mounting substrate 10C, compared to a case in which groove 14 is not filled with bonding component 80.

### Variation 4 of Embodiment 1

Next, Variation 4 of Embodiment 1 is described with reference to FIG. 8. FIG. 8 is a cross-sectional view of a portion of semiconductor laser light emitting device 1D according to Variation 4 of Embodiment 1. It should be noted that FIG. 8 corresponds to FIG. 2A that shows the portion of semiconductor laser light emitting device 1 according to above-described Embodiment 1.

As stated above, when step 11 is formed on mounting substrate by cutting or press working, curved portion 13 (the step radius) may be formed in the base portion of the inner lateral face of step 11 as shown in FIG. 8. For this reason, there is a possibility that when submount 20 is mounted on mounting substrate 10 using step 11, submount 20 runs onto curved portion 13 in the base portion of step 11 and is inclined.

With regard to this problem, although submount 20 is prevented from running onto curved portion 13 by providing groove 14 on mounting substrate 10C in above-described Variation 3, submount 20 is prevented from running onto curved portion 13 by disposing spacer 90 between submount 20 and mounting substrate 10 in the present variation.

Specifically, spacer 90 is disposed between first principal surface 10a of mounting substrate 10 (the bottom face of step 11) and bottom face 20d of submount 20. It should be noted that first principal surface 10a of mounting substrate 10 (the bottom face of step 11) and bottom face 20d of submount 20 are parallel to each other.

Front face 90a that is a face of spacer 90 on the light-emission direction side of semiconductor laser 30 is spaced part from the inner lateral face of step 11 by at least an amount equal to the width of curved portion 13. In this case, front face 90a of spacer 90 may be disposed apart from the inner lateral face of step 11 (lateral face 12b of protruding portion 12) by at least 10 μm and preferably at least 30 μm.

Moreover, spacer 90 has a thickness that is greater than or equal to the height of curved portion 13. In consideration of the above-described cutting or press working etc., spacer 90 may have a thickness of at least 10 μm and preferably at least 30 μm. In the present variation, spacer 90 has a thickness of 50 μm.

Spacer 90 is a tabular-shaped plate having a certain thickness. In addition, spacer 90 may include either a conductive material or an insulating material. However, spacer 90 may include a material having a high thermal conductivity. As an example, spacer 90 is a metal plate including a metal material such as copper or aluminum. Spacer 90 is attached with bonding component 80.

It should be noted that semiconductor laser light emitting device 1D according to the present variation has the same configuration as semiconductor laser light emitting device 1 according to above-described Embodiment 1, except that space 90 is disposed.

Accordingly, in the present variation, lateral face 12b of protruding portion 12, which is the inner lateral face of step 11, and front face 20a of submount 20, are also in thermal contact with each other. In addition, in the present variation, lateral face 12b of protruding portion 12, which is the inner lateral face of step 11, and front face 20a of submount 20, are also opposite to each other.

As with semiconductor laser light emitting device 1 according to above-described Embodiment 1, with regard to semiconductor laser light emitting device 1D according to the present variation, this configuration makes it possible not only to efficiently conduct the heat generated in semiconductor laser 30 to mounting substrate 10 via submount 20 but also to accurately mount semiconductor laser 30 on mounting substrate 10.

Moreover, in the present variation, spacer 90 is disposed apart from the inner lateral face of step 11 by the amount equal to the width of curved portion 13, and at the same time the thickness of spacer 90 is made greater than or equal to the width of curved portion 13.

Even when submount 20 is mounted on mounting substrate 10 using step 11 in the case where curved portion 13 (the step radius) is formed in the base portion of the inner lateral face of step 11, this configuration makes it possible to prevent submount 20 from being inclined as a result of a portion of front face 20a of submount 20 running onto curved portion 13. Accordingly, it is possible to mount submount 20 and semiconductor laser 30 mounted on submount 20 on mounting substrate 10 in a correct orientation.

It should be noted that although submount 20 is prevented from running onto curved portion 13 by disposing spacer 90 between mounting substrate 10 and submount 20 in the present variation, submount 20 may be prevented from running onto curved portion 13 without using spacer 90.

For example, by spacing a corner at which front surface 20a and bottom face 20d intersect apart from mounting substrate 10 when submount 20 is disposed on first principal surface 10a of mounting substrate 10 without interposing spacer 90 therebetween, it is possible to prevent submount 20 from running onto curved portion 13. In this case, front face 20a of submount 20 may be spaced apart from the inner lateral face of step 11 (lateral face 12b of protruding portion 12) by an amount equal to the width of curved portion 13.

Furthermore, in the present variation and above-described Variation 3, since step 11 is formed by performing cutting or press working on a portion of mounting substrate 10C, curved portion 13 (the step radius) is formed in the base portion of the inner lateral face of step 11. On the other hand, as in above-described Variation 2, since it is possible to prevent curved portion 13 (the step radius) from being formed in the base portion of the inner lateral face of step 11 (a base portion of lateral face 12b of second component 102) by bonding first component 101 and second component 102 that are separately provided to make mounting substrate 10B, it is possible to prevent submount 20 from running onto curved portion 13.

Additionally, it is possible to prevent submount 20 from running onto curved portion 13, by rounding a corner of submount 20 corresponding to the step radius more than the step radius.

### Embodiment 2

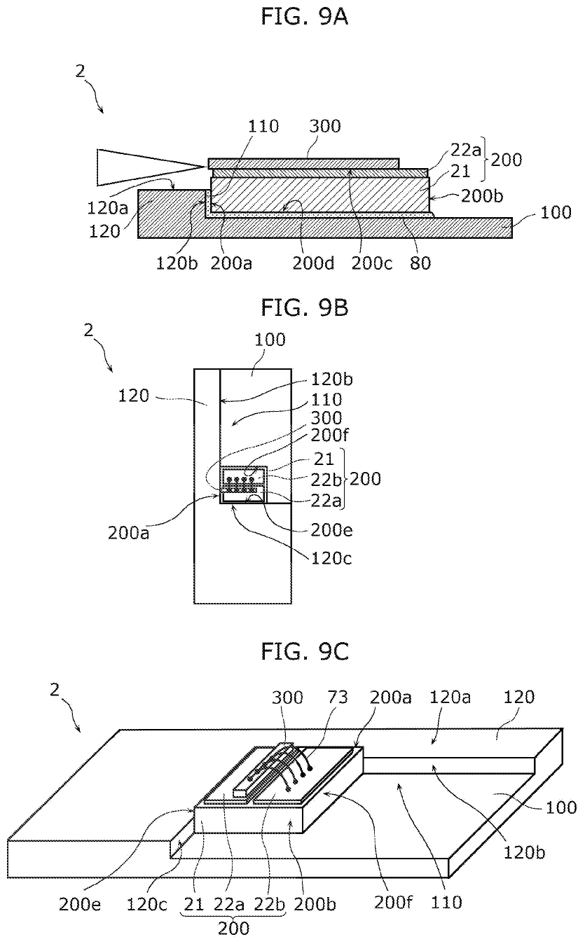

Next, semiconductor laser light emitting device 2 according to Embodiment 2 is described with reference to FIG. 9A, FIG. 9B, and FIG. 9C. FIG. 9A, FIG. 9B, and FIG. 9C are diagrams showing a portion of semiconductor laser light emitting device 2 according to Embodiment 2, and are a cross-sectional view, a top view, and a perspective view of the portion of semiconductor laser light emitting device 2, respectively. It should be noted that FIG. 9A, FIG. 9B, and FIG. 9C correspond to FIG. 2A, FIG. 2B, and FIG. 2C that show the portion of semiconductor laser light emitting device 1 according to above-described Embodiment 1, respectively.

As shown in FIG. 9A to FIG. 9C, as with semiconductor laser light emitting device 1 according to above-described Embodiment 1, step 110 is also formed by providing protruding portion 120 on mounting substrate 100 in semiconductor laser light emitting device 2 according to the present embodiment. Semiconductor laser light emitting device 2 according the present embodiment, however, differs from semiconductor laser light emitting device 1 according to above-described Embodiment 1 in the shapes of step 110 and protruding portion 120, an electrode structure of submount 200, and connection of gold wires 73.

Specifically, although step 11 includes only one inner lateral face as a face opposite to submount 20 in above-described Embodiment 1, step 110 includes two inner lateral faces as faces opposite to submount 200 in the present embodiment. More specifically, in the present embodiment, protruding portion 120 forming step 110 includes two different lateral faces that are first lateral face 120b and second lateral face 120c. First lateral face 120b of protruding portion 120 is a first lateral face formed as one inner lateral face of step 110, and second lateral face 120c of protruding portion 120 is a second lateral face formed as an other lateral face different from the first lateral face of step 110.

First lateral face 120b and second lateral face 120c in protruding portion 120 form a predetermined angle. In the present embodiment, first lateral face 120b and second lateral face 120c in protruding portion 120 are connected at a right angle to be substantially perpendicular to each other. In other words, first lateral face 120b and second lateral face 120c form a right angle in a top view. It should be noted that as with protruding portion 12 in Embodiment 1, protruding portion 120 includes planar top face 120a.

Moreover, as with submount 20 in Embodiment 1, submount 200 includes front face 200a, rear face 200b, top face 200c, and bottom face 200d. Furthermore, submount 200 includes lateral face 200e and lateral face 200f that are side faces.

In semiconductor laser light emitting device 2 according to the present embodiment, the first lateral face (first lateral face 120b of protruding portion 120) that is one inner lateral face of step 110 and front face 200a of submount 200 are in thermal contact with each other, and additionally the second lateral face (second lateral face 120c of protruding portion 120) that is an inner lateral face of step 110 different from the first lateral face and lateral face 200e of submount 200 are in thermal contact with each other.

In this case, the first lateral face of step 110 (first lateral face 120b of protruding portion 120) and front face 200a of submount 200 may be physically close to or in contact with each other. In addition, the second lateral face of step 110 (second lateral face 120c of protruding portion 120) and lateral face 200e of submount 200 may be physically close to or in contact with each other.

In the present embodiment, first lateral face 120b of protruding portion 120 and front face 200a of submount 200 are close to each other but not in direct contact with each other. Specifically, first lateral face 120b of protruding portion 120 and front face 200a of submount 200 are connected with only bonding component 80 being interposed therebetween. Likewise, second lateral face 120c of protruding portion 120 and lateral face 200e of submount 200 are close to each other but not in direct contact with each other. Specifically, second lateral face 120c of protruding portion 120 and lateral face 200e of submount 200 are connected with only bonding component 80 being interposed therebetween.

As stated above, in semiconductor laser light emitting device 2 according to the present embodiment, first lateral face 120b of protruding portion 120 (the first lateral face of step 110) and front face 200a of submount 200 are in thermal contact with each other, and additionally second lateral face 120c of protruding portion 120 (the second lateral face of step 110) and lateral face 200e of submount 200 are in thermal contact with each other. To put it differently, the two different inner lateral faces of step 110 are opposite to and in thermal contact with the two different faces of submount 200.

When heat generated in semiconductor laser 300 is conducted to mounting substrate 100 using step 110, this configuration makes it possible to conduct the heat generated in semiconductor laser 300 in two different directions of a substrate horizontal direction. Specifically, the heat generated in semiconductor laser 300 is conducted to mounting substrate 100 from front face 200a of submount 200 through first lateral face 120b of protruding portion 120, and is also conducted to mounting substrate 100 from lateral face 200e of submount 200 through second lateral face 120c of protruding portion 120. Accordingly, it is possible to more efficiently conduct the heat generated in semiconductor laser 300 to mounting substrate 100 than semiconductor laser light emitting device 1 according to above-described Embodiment 1.

Moreover, the present embodiment also makes it possible to align submount 200 using step 110 when submount 200 is mounted on mounting substrate 100. Furthermore, the present embodiment makes it possible to determine the position of submount 200 in the two different directions of the substrate horizontal direction using step 110. Specifically, by pressing lateral face 200e of submount 200 to second lateral face 120c of protruding portion 120 while pressing front face 200a of submount 200 to first lateral face 120b of protruding portion 120, it is possible to mount submount 200, on which semiconductor laser 300 is disposed, at a predetermined position of mounting substrate 100. Accordingly, it is possible to improve the accuracy of mounting semiconductor laser 300 on mounting substrate 100 more than semiconductor laser light emitting device 1 according to above-described Embodiment 1.

As stated above, semiconductor laser light emitting device 2 according to the present embodiment makes it possible to improve the heat dissipation performance and mounting accuracy of semiconductor laser 300 more than semiconductor laser light emitting device 1 according to above-described Embodiment 1.

Moreover, semiconductor laser light emitting device 2 according to the present embodiment also differs from semiconductor laser light emitting device 1 according to above-described Embodiment 1 in disposition of semiconductor laser 300. Specifically, semiconductor laser 300 is disposed horizontally offset relative to submount 200. More specifically, semiconductor laser 300 is disposed offset to be closer to lateral face 200e among lateral face 200e and lateral face 200f of submount 200 that are opposite to each other. For example, when submount 200 has a width (a distance between lateral face 200f and lateral face 200e) of 1000 μm, semiconductor laser 300 is disposed offset to cause a distance between lateral face 200e of submount 200 and the center of semiconductor laser 300 to be 300 μm in a top view.

Since semiconductor laser 300 is disposed horizontally offset as above, first electrode 22a and second electrode 22b that are horizontally insulation-separated are provided on a top face of submount body 21 of submount 200. Although the electrodes of submount 200 are horizontally separated in the present embodiment, a structure in which only first electrode 22a is provided may be used as in Embodiment 1.

Semiconductor laser 300 is disposed on first electrode 22a. Since semiconductor laser 300 is also mounted on submount 200 by junction-down mounting in the present embodiment, first electrode 22a is connected to a p-side electrode of semiconductor laser 300. In contrast, second electrode 22b is connected to an n-side electrode of semiconductor laser 300 with gold wires 73.

As stated above, when semiconductor laser 300 is disposed horizontally offset on submount 200, as in the present embodiment, first lateral face 120b of protruding portion 120 (the first lateral face of step 110) may be caused to be in thermal contact with front face 200a of submount 200, and additionally second lateral face 120c of protruding portion 120 (the second lateral face of step 110) may be caused to be in thermal contact with lateral face 200e of submount 200 on a side to which semiconductor laser 300 is located closer.

This makes it possible not only to more efficiently conduct the heat generated in semiconductor laser 300 to mounting substrate 100 but also to readily improve the mounting accuracy of semiconductor laser 300.

It should be noted that it is possible to apply the structures, materials, and disposition etc. of the mounting substrate, the submount, and the semiconductor laser in each of above-described Embodiment 1 and the variations thereof to the structures, materials, and disposition etc. of mounting substrate 100, submount 200, and semiconductor laser 300 in the present embodiment.

### Variation of Embodiment 2

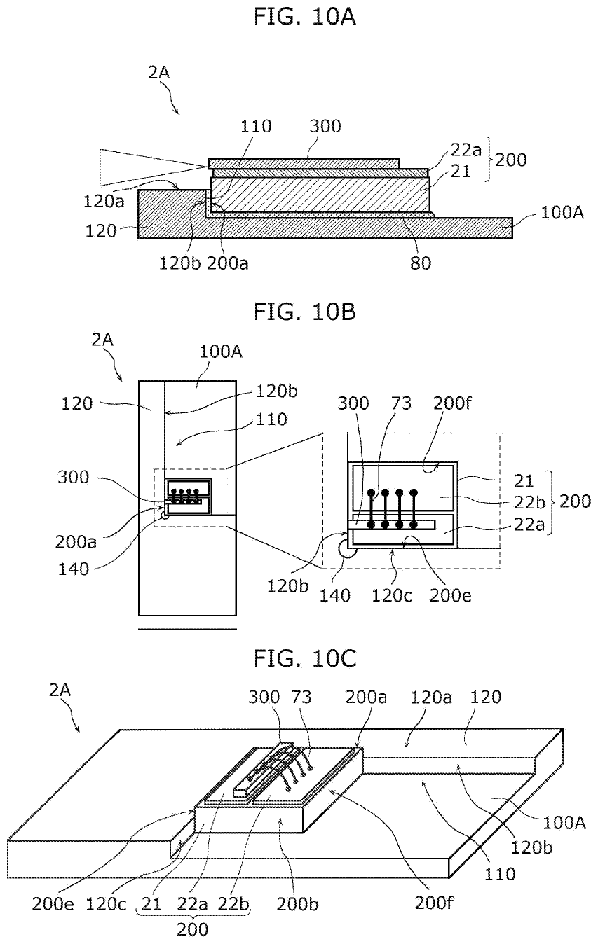

Next, a variation of Embodiment 2 is described with reference to FIG. 10A, FIG. 10B, and FIG. 10C. FIG. 10A, FIG. 10B, and FIG. 10C are diagrams showing a portion of semiconductor laser light emitting device 2A according to the variation of Embodiment 2, and are a cross-sectional view, a top view, and a perspective view of the portion of semiconductor laser light emitting device 2A, respectively. It should be noted that FIG. 10A, FIG. 10B, and FIG. 10C correspond to FIG. 9A, FIG. 9B, and FIG. 9C that show the portion of semiconductor laser light emitting device 2 according to above-described Embodiment 2, respectively.

When step 110 is formed on mounting substrate 100 by cutting using a drill or laser or by press working in above-described Embodiment 2, a corner radius may be formed in a corner portion of step 110 as a result of the corner portion formed by the first lateral face of step 110 (first lateral face 120b of protruding portion 120) and the second lateral face of step 110 (second lateral face 120c of protruding portion 120) being curved in a top view. In other words, the corner portion of step 110 is not at a right angle, and a curved portion that curves in a cross-sectional arc-like shape may be formed in the corner portion of step 110 as a result of the corner portion of step 110 being rounded in the top view.

As stated above, when the curved portion (the corner radius) is formed in the corner portion of step 110, there is a possibility that when submount 200 is mounted on mounting substrate 100A while determining the position of submount 200 using step 110, a portion of front face 200a of submount 200 runs onto the curved portion, and submount 200 rotates horizontally. In this case, there is a possibility that semiconductor laser 300 mounted on submount 200 also rotates horizontally, and semiconductor laser 300 is not mounted on mounting substrate 100A in a correct orientation.

In view of this, as shown in FIG. 10B, in semiconductor laser light emitting device 2A according to the present variation, groove 140 greater than the curved portion formed in the corner portion of step 110 is formed in the corner portion of step 110 of mounting substrate 100A in the top view. In the present variation, groove 140 notches the corner portion of step 110 to form a recessed portion in a circular shape from the corner portion of step 110 in the top view.

In consideration of the above-described cutting or press working etc., the amount of recession of groove 140 from each of first lateral face 120b and second lateral face 120c (i.e., the amount of recession of groove 140 in two perpendicular directions of the horizontal direction) may be at least 10 μm and preferably at least 30 μm. In the present variation, groove 140 is formed in a ¾ of a circular shape (a fan shape having a circumferential angle of 270°) having a radius of 50 μm to recede from each of first lateral face 120b and second lateral face 120c by 50 μm in the top view.

It should be noted that semiconductor laser light emitting device 2A according to the present variation has the same configuration as semiconductor laser light emitting device 2 according to above-described Embodiment 2, except that groove 140 is formed on mounting substrate 100A.

Accordingly, in the present variation, first lateral face 120b of protruding portion 120 (the first lateral face of step 110) and front face 200a of submount 200 are also in thermal contact with each other, and additionally second lateral face 120c of protruding portion 120 (the second lateral face of step 110) and lateral face 200e of submount 200 are also in thermal contact with each other. To put it differently, the two different inner lateral faces of step 110 are opposite to and in thermal contact with the two different faces of submount 200.

As with semiconductor laser light emitting device 2 according to above-described Embodiment 2, with regard to semiconductor laser light emitting device 2A according to the present variation, this configuration makes it possible not only to efficiently conduct the heat generated in semiconductor laser 300 to mounting substrate 100A via submount 200 but also to accurately mount semiconductor laser 300 on mounting substrate 100A.

Moreover, in the present variation, groove 140 is formed in the corner portion of step 110 of mounting substrate 100A in the top view.

Since this configuration makes it possible to remove the curved portion (the corner radius) in the corner portion of step 110 of mounting substrate 100A, even when submount 200 is mounted on mounting substrate 100A using step 110 while determining the position of submount 200, it is possible to prevent submount 200 from rotating horizontally as a result of submount 200 running onto the curved portion. Accordingly, it is possible to mount submount 200 and semiconductor laser 300 mounted on submount 200 on mounting substrate 100A in a correct orientation.

It should be noted that although submount 200 is prevented from running onto the curved portion by forming groove 140 in the corner portion of step 110 in the present variation, submount 200 may be prevented from running onto the curved portion without forming groove 140.

For example, in the case where groove 140 is not formed on mounting substrate 100C, in the top view, even when the curved portion (the corner radius) is formed in the corner portion of step 110, by spacing a corner at which front face 200a and lateral face 200e of submount 200 intersect apart from mounting substrate 100C, it is possible to prevent submount 200 from running onto the curved portion. In this case, submount 200 may be spaced apart from the two inner lateral faces of step 110 (first lateral face 120b and second lateral face 120c of protruding portion 120) by rounding a corner of submount 200 corresponding to the above-described corner radius more than the corner radius or by providing spacer 90 as described in Variation 4 of Embodiment 1 on front face 200a and lateral face 200e of submount 200.

### Embodiment 3

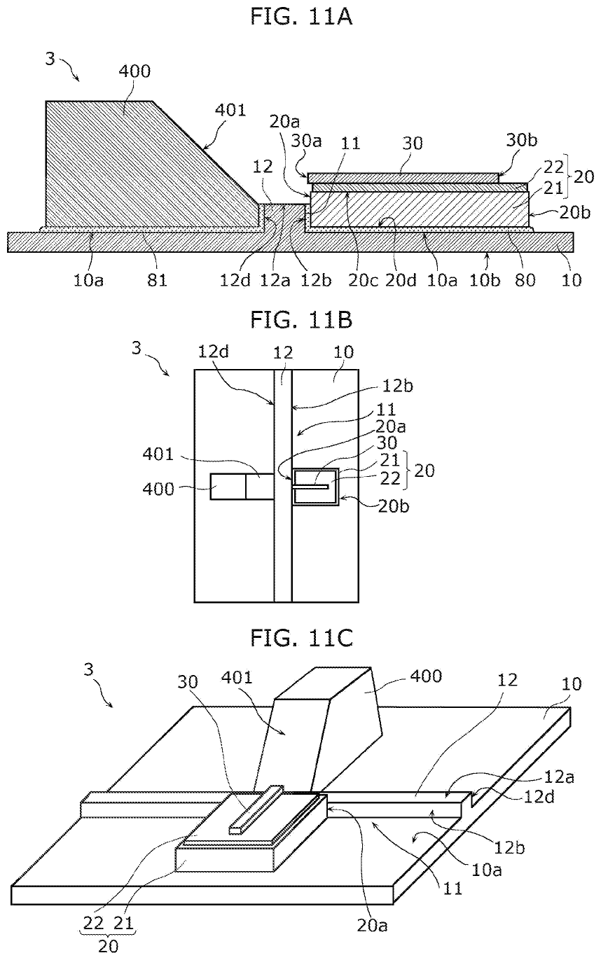

Next, semiconductor laser light emitting device 3 according to Embodiment 3 is described with reference to FIG. 11A, FIG. 11B, and FIG. 11C. FIG. 11A, FIG. 11B, and FIG. 11C are diagrams showing a portion of semiconductor laser light emitting device 3 according to Embodiment 3, and are a cross-sectional view, a top view, and a perspective view of the portion of semiconductor laser light emitting device 3, respectively. It should be noted that FIG. 11A, FIG. 11B, and FIG. 11C correspond to FIG. 2A, FIG. 2B, and FIG. 2C that show the portion of semiconductor laser light emitting device 1 according to above-described Embodiment 1, respectively.

As shown in FIG. 11A to FIG. 11C, semiconductor laser light emitting device 3 according to the present embodiment differs from semiconductor laser light emitting device 1 according to above-described Embodiment 1 in further including mirror 400 that reflects light emitted from semiconductor laser 30.

Mirror 400 includes reflective surface 401 that reflects incident light. In the present embodiment, mirror 400 is an upward-reflecting mirror, and reflective surface 401 reflects incident light upwardly in a rising manner.

Reflective surface 401 of mirror 400 is an inclined surface inclined to first principal surface 10a of mounting substrate 10. As an example, an inclination angle of reflective surface 401 to first principal surface 10a of mounting substrate 10 is 45 degrees. In this case, light emitted from semiconductor laser 30 in a direction parallel to first principal surface 10a of mounting substrate 10 is reflected by reflective surface 401 of mirror 400, and travels toward an upper side that is a direction perpendicular to first principal surface 10a of mounting substrate 10.

For this reason, although not shown in the figure, unlike above-described Embodiment 1, in the present embodiment, light-transmissive component 50 that transmits light emitted from semiconductor laser 30 is disposed to cover not the opening portion of frame 40 but an opening provided to the top cover.

Moreover, protruding portion 12 provided on mounting substrate 10 includes lateral face 12d opposite to lateral face 12b. Since protruding portion 12 is a cuboid, lateral face 12b and lateral face 12d are parallel to each other and are in the same rectangular shape. When a lateral face of step 11 that is lateral face 12b of protruding portion 12 is defined as a first lateral face, mounting substrate 10 includes, as a face parallel to the first lateral face, a third lateral face that is lateral face 12d of protruding portion 12.

Mirror 400 is in contact with lateral face 12d of protruding portion 12 (the third lateral face). Specifically, a lower end portion of mirror 400 on a reflective surface 401 side (the semiconductor laser side) abuts on lateral face 12d of protruding portion 12.

Mirror 400 is disposed in a position opposite to submount 20. Submount 20 and mirror 400 are disposed with protruding portion 12 being interposed therebetween. Specifically, submount 20 is disposed in contact with lateral face 12b of protruding portion 12, and mirror 400 is disposed in contact with lateral face 12d of protruding portion 12. In other words, submount 20 and mirror 400 are disposed to sandwich protruding portion 12 therebetween.

Mirror 400 is bonded to mounting substrate 10 with bonding component 81. Accordingly, it is possible to attach mirror 400 to mounting substrate 10. It should be noted that the same bonding component as bonding component 80 can be used as bonding component 81.

It should be noted that semiconductor laser light emitting device 3 according to the present embodiment basically has the same configuration as semiconductor laser light emitting device 1 according to above-described Embodiment 1, except that mirror 400 is disposed.

Accordingly, in the present variation, lateral face 12b of protruding portion 12, which is the inner lateral face of step 11, and front face 20a of submount 20, are also in thermal contact with each other, and additionally lateral face 12b of protruding portion 12, which is the inner lateral face of step 11, and front face 20a of submount are also opposite to each other.

As with semiconductor laser light emitting device 1 according to above-described Embodiment 1, with regard to semiconductor laser light emitting device 3 according to the present embodiment, this configuration makes it possible not only to efficiently conduct the heat generated in semiconductor laser 30 to mounting substrate 10 but also to accurately mount semiconductor laser 30 on mounting substrate 10, using step 11 (protruding portion 12).

Additionally, in semiconductor laser light emitting device 3 according to the present embodiment, mirror 400 is in contact with lateral face 12d of protruding portion 12.

This configuration allows step 11 formed on mounting substrate to serve not only as a reference for aligning submount 20 and semiconductor laser 30 with mounting substrate 10 but also as a reference for aligning mirror 400 with mounting substrate 10. For example, when mirror 400 is mounted on mounting substrate 10, it is possible to mount mirror 400 at a predetermined position of mounting substrate 10 by pressing mirror 400 to lateral face 12d of protruding portion 12. In other words, step 11 (protruding portion 12) formed on mounting substrate 10 makes it possible to determine the position of mirror 400 in the substrate horizontal direction. Accordingly, it is also possible to improve the accuracy of mounting mirror 400 on mounting substrate 10.

As stated above, in semiconductor laser light emitting device 3 according to the present embodiment, it is possible not only to determine the positions of semiconductor laser 30 and submount 20 but also to determine the position of mirror 400, using step 11 (protruding portion 12) formed on mounting substrate 10.

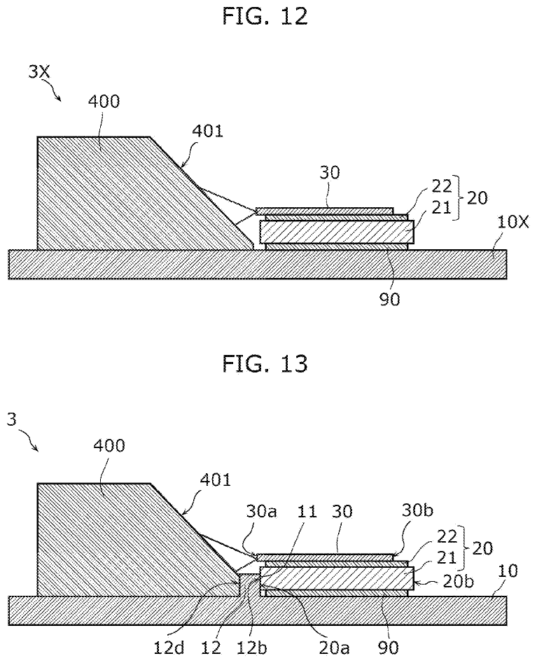

Here, the following describes the results of simulations performed with regard to effects on heat dissipation of semiconductor laser light emitting device 3 according to the present embodiment, compared to semiconductor laser light emitting device 3X according to Comparative Example 2. FIG. 12 is a cross-sectional view of a configuration of semiconductor laser light emitting device 3X according to Comparative Example 2. FIG. 13 is a cross-sectional view of a configuration of semiconductor laser light emitting device 3 according to Embodiment 3.

As shown in FIG. 12, semiconductor laser light emitting device 3X according to Comparative Example 2 differs from semiconductor laser light emitting device 3 according to the present embodiment shown in FIG. 13 in having a structure in which step 11 is not formed on mounting substrate 10X. Specifically, in semiconductor laser light emitting device 3X according to Comparative Example 2, protruding portion 12 is not provided on mounting substrate 10X.

It should be noted that in semiconductor laser light emitting device 3 shown in FIG. 13, spacer 90 is disposed between submount and mounting substrate 10. Likewise, in semiconductor laser light emitting device 3X according to Comparative Example 2, spacer 90 is disposed between submount 20 and mounting substrate 10X.

In the simulations: mounting substrate 10 and mounting substrate 10X each were a copper substrate; submount body 21 of submount 20 was an aluminum nitride plate that was a cuboid having a length of 1400 μm in a longitudinal direction of semiconductor laser 30, a length of 1000 μm in a direction perpendicular to the longitudinal direction of semiconductor laser 30, and a thickness of 200 μm; electrode 22 of submount 20 was a copper thick film having a thickness of 50 μm; spacer 90 was a copper thick film having a thickness of 50 μm; and semiconductor laser 30 was a GaN semiconductor laser element having a length of 1200 μm in the resonator length direction, a length of 150 μm in a direction perpendicular to the resonator length direction, and a thickness of 90 μm. It should be noted that semiconductor laser 30 had a beam spread angle of 46°. Moreover, semiconductor laser 30 was disposed, on submount 20, at a position that caused a distance between front end face 30a and front face 20a of submount (the amount of protrusion from submount 20) to be 10 μm, and caused a horizontal distance from front end face 30a of semiconductor laser 30 to reflective surface 401 of mirror 400 to be 320 μm. It should be noted that a distance from rear end face 30b of semiconductor laser 30 to rear face 20b of submount 20 was 210 μm. Furthermore, protruding portion 12 of mounting substrate 10 in FIG. 13 was a copper block that was a cuboid having a cross-sectional height of 200 μm and a width of 200 μm. Protruding portion 12 had a length of 1000 μm to cover the entire transverse width of front face 20a of submount 20.

A heat transfer analysis was performed on each of semiconductor laser light emitting device 3X according to Comparative Example 2 and semiconductor laser light emitting device 3 according to the present embodiment. It was found that the maximum temperature of semiconductor laser 30 was 59.1° C. in semiconductor laser light emitting device 3X according to Comparative Example 2. In contrast, it was found that the maximum temperature of semiconductor laser 30 was 57.8° C. in semiconductor laser light emitting device 3 according to the present embodiment. In this manner, it was found out that providing protruding portion 12 on mounting substrate 10 made it possible to decrease the maximum temperature of semiconductor laser 30 by as much as approximately 1.3° C.

Moreover, assuming that power applied to semiconductor laser was 7.4 W and an environment temperature was 25° C., a thermal resistance (=(maximum temperature−25° C.) was calculated for each of semiconductor laser light emitting device 3X according to Comparative Example 2 and semiconductor laser light emitting device 3 according to the present embodiment. It was found that a thermal resistance was approximately 4.61 [° C./W] in semiconductor laser light emitting device 3X according to Comparative Example 2. In contrast, it was found that a thermal resistance was approximately 4.44 [° C./W] in semiconductor laser light emitting device 3 according to the present embodiment. In this manner, it was found out that providing protruding portion 12 on mounting substrate 10 made it possible to decrease the maximum temperature of semiconductor laser 30 by 1.3° C., which resulted in decreasing the thermal resistance by as much as approximately 0.17 [° C./W]. To put it differently, it was found out that semiconductor laser light emitting device 3 according to the present embodiment made it possible to efficiently conduct heat generated in semiconductor laser 30 to mounting substrate 10.

As stated above, semiconductor laser light emitting device 3 according to the present embodiment is superior in heat dissipation performance of semiconductor laser 30.

It should be noted that although the positions of semiconductor laser 30 and submount 20 are determined using one step 11 (protruding portion 12) in the present embodiment, the present disclosure is not limited to this example. For example, a step (a protruding portion or a recessed portion) may be formed on mounting substrate 10 separately from step 11 (protruding portion 12), and a position of mirror 400 may be determined using the step (the protruding portion or the recessed portion). In this case, the other step (the protruding portion or the recessed portion) may be formed at a position on a side opposite to the reflective surface 401 side of mirror 400 (behind mirror 400).

Moreover, mirror 400 is mounted on mounting substrate 10 by bringing mirror 400 into contact with lateral face 12d of protruding portion 12 in the present embodiment, the present disclosure is not limited to this example. Specifically, mirror 400 may be disposed without being in contact with lateral face 12d of protruding portion 12, in conformance to a distance to semiconductor laser 30, an orientation of semiconductor laser 30, etc.

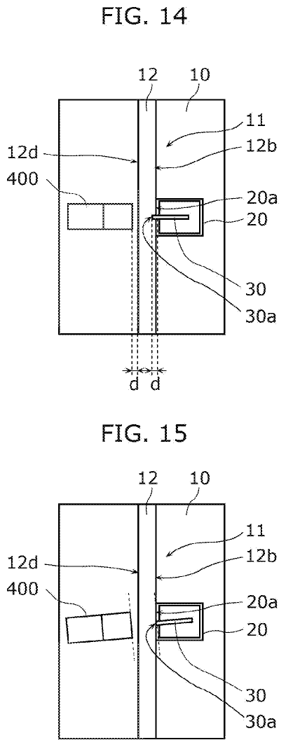

For example, as shown in FIG. 14, when semiconductor laser protrudes to protruding portion 12 (step 11), mirror 400 may be disposed apart from protruding portion 12 to cause a distance between front end face 30a of semiconductor laser 30 and mirror 400 to be a predetermined value. Specifically, when front end face 30a of semiconductor laser 30 protrudes from a predetermined reference position by distance d (e.g., 20 μm), mirror 400 may be disposed apart from lateral face 12d of protruding portion 12 by distance d (e.g., 20 μm).

Alternatively, as shown in FIG. 15, when semiconductor laser is inclined to an inner lateral face of step 11 (lateral face 12b of protruding portion 12), mirror 400 may be disposed inclined to the inner lateral face of step 11 (lateral face 12b of protruding portion 12) in conformance to the inclination of semiconductor laser 30, to reflect light emitted from semiconductor laser 30 in a predetermined direction. For example, when semiconductor laser 30 is mounted with front end face 30a of semiconductor laser 30 being inclined to lateral face 12b of protruding portion 12 or front face 20a of submount by 1.5°, mirror 400 is disposed with a front face of mirror 400 being inclined to lateral face 12b of protruding portion 12 or front face of submount 20 by 1.5°. It should be noted that it is also possible to apply the configurations of Variations 1 to 3 of Embodiment 1 and Embodiment 2 to the present embodiment.

### Embodiment 4

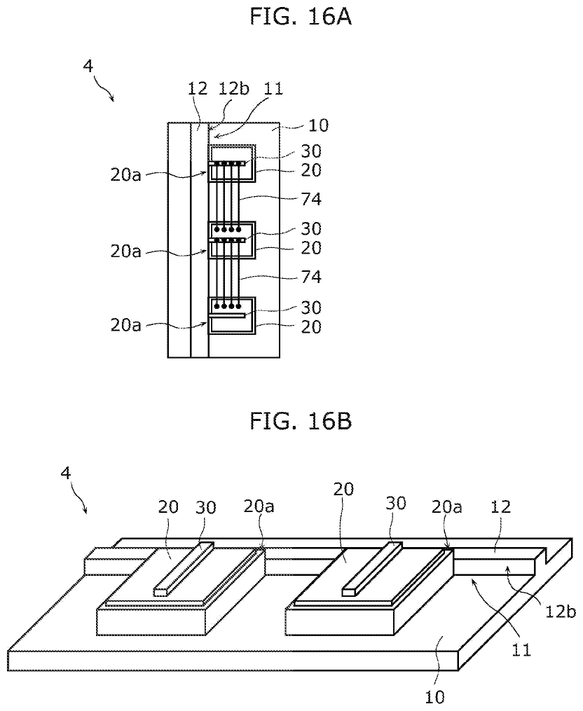

Next, semiconductor laser light emitting device 4 according to Embodiment 4 is described with reference to FIG. 16A and FIG. 16B. FIG. 16A and FIG. 16B are diagrams showing a portion of semiconductor laser light emitting device 4 according to Embodiment 4, and are a top view and a perspective view of the portion of semiconductor laser light emitting device 4, respectively. It should be noted that FIG. 16A and FIG. 16B correspond to FIG. 2B and FIG. 2C that show the portion of semiconductor laser light emitting device 1 according to above-described Embodiment 1, respectively.

As shown in FIG. 16A and FIG. 16B, semiconductor laser light emitting device 4 according to the present embodiment is a multi-chip semiconductor laser light emitting device obtained using a plurality of semiconductor lasers 30. This allows semiconductor laser light emitting device 4 to achieve high power.

Specifically, semiconductor laser light emitting device 4 according to the present embodiment has a configuration obtained by pluralizing each of submount 20 and semiconductor laser 30 in semiconductor laser light emitting device 1 according to above-described Embodiment 1. Each of the plurality of semiconductor lasers 30 is disposed on a different one of the plurality of submounts 20. In other words, the plurality of submounts 20 and the plurality of semiconductor lasers 30 correspond one-to-one with each other.

FIG. 16A shows an example in which three submounts 20 and three semiconductor lasers 30 are disposed. Stated differently, three module sets each including one semiconductor laser 30 and one submount 20 are disposed on mounting substrate 10. The three module sets are disposed at evenly spaced intervals in the longitudinal direction of protruding portion 12. In the present embodiment, the three module sets are disposed at evenly spaced intervals of 3.5 mm.

Moreover, in the three module sets, two adjacent semiconductor lasers 30 are connected with gold wires 74. To put it differently, the plurality of semiconductor lasers 30 are electrically connected in series.

It should be noted that FIG. 16B shows two of the three module sets shown in FIG. 16A. In addition, gold wires 74 are omitted from FIG. 16B.

With regard to each of the plurality of submounts 20, as with above-described Embodiment 1, lateral face 12b of protruding portion 12, which is the inner lateral face of step 11, and front face 20a of submount 20, are in thermal contact with each other. In other words, front face 20a of each of the plurality of submounts 20 and the inner lateral face of step 11 (lateral face 12b of protruding portion 12) of mounting substrate 10 are in thermal contact with each other. In this case, front face 20a of submount 20 may be physically close to or in contact with the inner lateral face of step 11 (lateral face 12b of protruding portion 12). Additionally, in the present embodiment, with regard to each of the plurality of submounts 20, the inner lateral face of step 11 (lateral face 12b of protruding portion 12) and front face 20a of submount 20 are also opposite to each other.

Here, step 11 opposite to front faces 20a of the plurality of submounts 20 is a single structure (a cuboid). It is possible to manufacture lateral face 12b of step 11 in a linear manner. Accordingly, since causing front faces 20a of the plurality of submounts 20 to oppose one common lateral face 12b results in one reference for determining the positions of semiconductor lasers 30, it is possible to make a position accuracy in one direction uniform.

As with semiconductor laser light emitting device 1 according to above-described Embodiment 1, with regard to semiconductor laser light emitting device 4 according to the present embodiment, this configuration makes it possible not only to efficiently conduct heat generated in each semiconductor laser 30 to mounting substrate 10 but also to accurately mount semiconductor laser 30 on mounting substrate 10.

### Variation 1 of Embodiment 4

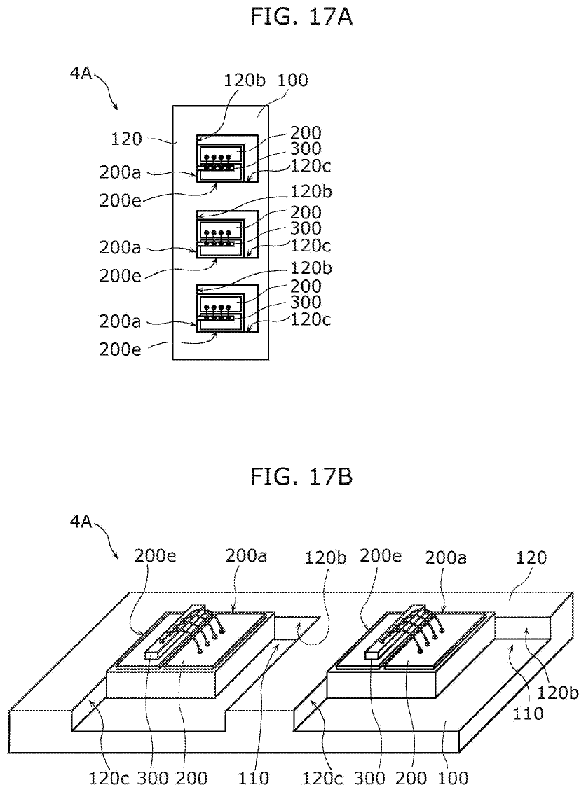

Next, Variation 1 of Embodiment 4 is described with reference to FIG. 17A and FIG. 17B. FIG. 17A and FIG. 17B are diagrams showing a portion of semiconductor laser light emitting device 4A according to Variation 1 of Embodiment 4, and are a top view and a perspective view of the portion of semiconductor laser light emitting device 4A, respectively. It should be noted that FIG. 17A and FIG. 17B correspond to FIG. 16A and FIG. 16B that show the portion of semiconductor laser light emitting device 4 according to above-described Embodiment 4, respectively. It should be noted that FIG. 17B shows two of three module sets shown in FIG. 17A.

Semiconductor laser light emitting device 4A according to the present variation is obtained by applying the configuration of semiconductor laser light emitting device 2 according to above-described Embodiment 2 to semiconductor laser light emitting device 4 according to above-described Embodiment 4.

Specifically, step 110 includes two inner lateral faces as faces opposite to submount 200 in semiconductor laser light emitting device 4A according to the present variation, whereas step 11 includes the only one inner lateral face as a face opposite to submount 20 in semiconductor laser light emitting device 4 according to above-described Embodiment 4.

In the present variation, protruding portion 120 forming step 110 includes two different lateral faces that are first lateral face 120b and second lateral face 120c. First lateral face 120b of protruding portion 120 is a first lateral face formed as one inner lateral face of step 110, and second lateral face 120c of protruding portion 120 is a second lateral face formed as an other lateral face of step 110 different from the first lateral face.

As with above-described Embodiment 2, first lateral face 120b and second lateral face 120c of protruding portion 120 are also connected to be substantially perpendicular to each other in the present variation. In the present variation, however, since the plurality of submounts 200 are disposed, protruding portion 120 includes a plurality of first lateral faces 120b and a plurality of second lateral faces 120c.

Moreover, as with above-described Embodiment 2, semiconductor laser 300 is disposed offset to be closer to lateral face 200e among lateral face 200e and lateral face 200f of submount 200 that are opposite to each other.

As with above-described Embodiment 2, in semiconductor laser light emitting device 4 according to the present variation, with regard to each submount 200, the first lateral face (first lateral face 120b of protruding portion 120), which is one inner lateral face of step 110, and front face 200a of submount 200, are in thermal contact with each other, and additionally the second lateral face (second lateral face 120c of protruding portion 120), which is an inner lateral face of step 110 different from the first lateral face, and lateral face 200e of submount 200, are in thermal contact with each other.

In other words, each of the plurality of first lateral faces 120b of protruding portion 120 and a different one of front faces 200a of the plurality of submounts 200 are in thermal contact with each other, and additionally time each of the plurality of second lateral faces 120c of protruding portion 120 and a different one of lateral faces 200e of the plurality of submounts 200 are in thermal contact with each other. In particular, with regard to each submount 200, lateral face 200e of submount 200, to which semiconductor laser 300 is disposed offset to be closer, is in thermal contact with second lateral face 120c of protruding portion 120.

With this configuration, heat generated in each semiconductor laser 300 is conducted to mounting substrate 100 from front face 200a of each submount 200 through first lateral face 120b of protruding portion 120, and is also conducted to mounting substrate 100 from lateral face 200e of each submount 200 through second lateral face 120c of protruding portion 120. Accordingly, it is possible to more efficiently conduct the heat generated in semiconductor laser 300 to mounting substrate 100 than semiconductor laser light emitting device 4 according to above-described Embodiment 4.

Additionally, as with above-described Embodiment 2, in the present variation, it is possible to determine the position of each submount 200 in two different directions of the substrate horizontal direction, using step 110. As a result, it is possible to improve the accuracy of mounting each semiconductor laser 300 on mounting substrate 100 in the two directions as a whole more than semiconductor laser light emitting device 4 according to above-described Embodiment 4.

As stated above, semiconductor laser light emitting device 4A according to the present variation makes it possible to improve the heat dissipation performance and mounting accuracy of semiconductor laser 300 more than semiconductor laser light emitting device 4 according to above-described Embodiment 4.

It should be noted that the plurality of semiconductor lasers 300 may be electrically connected in series with, for example, gold wires.

### Variation 2 of Embodiment 4

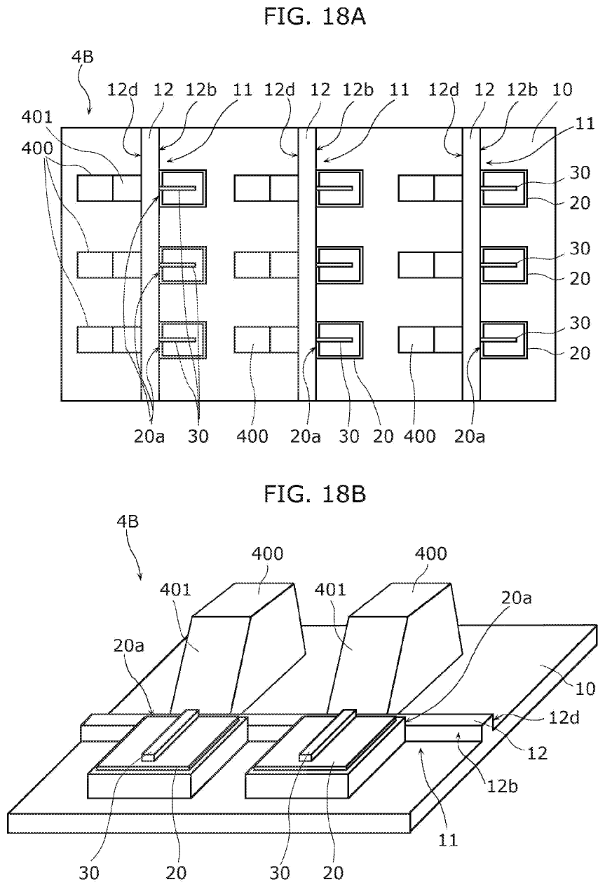

Next, Variation 2 of Embodiment 4 is described with reference to FIG. 18A and FIG. 18B. FIG. 18A and FIG. 18B are diagrams showing a portion of semiconductor laser light emitting device 4B according to Variation 2 of Embodiment 4, and are a top view and a perspective view of the portion of semiconductor laser light emitting device 4B, respectively. It should be noted that FIG. 18A and FIG. 18B correspond to FIG. 16A and FIG. 16B that show the portion of semiconductor laser light emitting device 4 according to above-described Embodiment 4, respectively.

Semiconductor laser light emitting device 4B according to the present variation is obtained by applying the configuration of semiconductor laser light emitting device 3 according to above-described Embodiment 3 to semiconductor laser light emitting device 4 according to above-described Embodiment 4.

Specifically, as shown in FIG. 18A and FIG. 18B, semiconductor laser light emitting device 4B according to the present variation is obtained by causing semiconductor laser light emitting device 4 according to above-described Embodiment 4 to further include a plurality of mirrors 400 each corresponding to a different one of a plurality of semiconductor lasers 30. The plurality of mirrors 400 are disposed one-to-one with the plurality of semiconductor lasers 30 and each reflect light emitted from a corresponding one of the plurality of semiconductor lasers 30.

As with above-described Embodiment 3, each mirror 400 is an upward-reflecting mirror including reflective surface 401 that reflects incident light upwardly in a rising manner.

Each mirror 400 is in contact with lateral face 12d of protruding portion 12 (the third lateral face) that is opposite to lateral face 12b of protruding portion 12. Specifically, a lower end portion of each mirror 400 on the reflective surface 401 side (the semiconductor laser side) abuts on lateral face 12d of protruding portion 12.

Each mirror 400 is disposed at a position opposite to corresponding submount 20. A set of submount 20 and mirror 400 are disposed with protruding portion 12 being interposed therebetween. Specifically, submount 20 is disposed in contact with lateral face 12b of protruding portion 12, and mirror 400 is disposed in contact lateral face 12d of protruding portion 12. In other words, the set of submount 20 and mirror 400 are disposed to sandwich protruding portion 12 therebetween.

As shown in FIG. 18A, in the present variation, nine module sets each including one semiconductor laser 30 and one submount 20 are disposed. Specifically, modules each including semiconductor laser 30 and submount 20 are disposed in a matrix with three rows and three columns. Accordingly, nine mirrors 400 are disposed in a matrix with three rows and three columns.

In this case, as shown in FIG. 18A, three protruding portions 12 are provided on mounting substrate 10. Three module sets each including semiconductor laser 30 and submount 20 and three mirrors 400 are disposed on each protruding portion 12. It should be noted that FIG. 18B shows two of the nine module sets shown in FIG. 18A.

In the present variation, in each submount 20, the inner lateral face of step 11 (lateral face 12b of protruding portion 12) and front face 20a of submount 20 are in thermal contact with each other, and additionally the inner lateral face of step 11 (lateral face 12b of protruding portion 12) and front face 20a of submount 20 are opposite to each other.

As with semiconductor laser light emitting device 4 according to above-described Embodiment 4, with regard to semiconductor laser light emitting device 4B according to the present variation, this configuration makes it possible not only to efficiently conduct heat generated in semiconductor laser 30 to mounting substrate 10 but also to accurately mount semiconductor laser 30 on mounting substrate 10, using step 11 (protruding portion 12).

Moreover, as with above-described Embodiment 3, each mirror 400 is in contact with lateral face 12d of protruding portion 12 in semiconductor light emitting device 4B according to the present variation.

This configuration makes it possible to use step 11 formed on mounting substrate 10 as a reference for aligning submount 20 and semiconductor laser 30 with mounting substrate 10, and at the same time to use step 11 as a reference for adjusting the position of mirror 400 relative to mounting substrate 10. In other words, step 11 (protruding portion 12) formed on mounting substrate 10 makes it possible to determine the position of mirror 400 in the substrate horizontal direction. Accordingly, it is possible to make a position accuracy of mirror 400 relative to mounting substrate 10 in one direction uniform.

### Other Variations

Although the semiconductor laser light emitting device according to the present disclosure has been described above based on the embodiments, the present disclosure is not limited to the above-described embodiments.

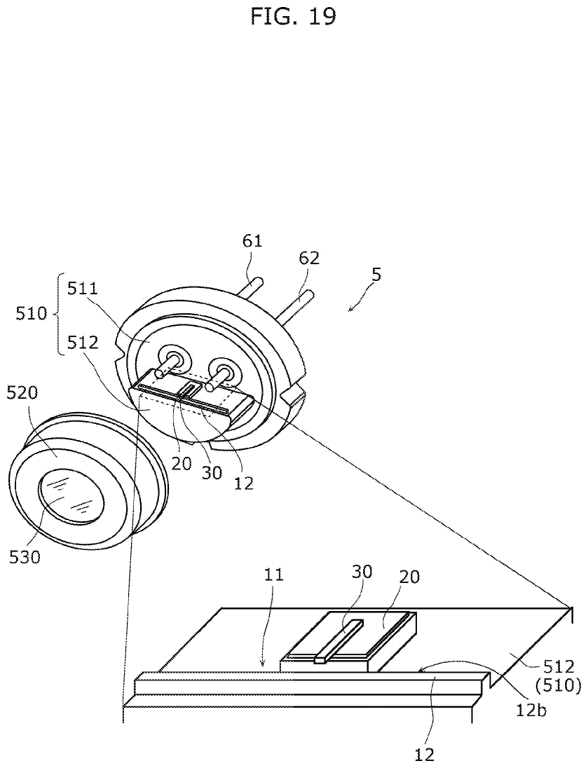

For example, although the semiconductor laser light emitting device according to above-described Embodiment 1 etc. is of a cuboid box package type, the present disclosure is not limited to this example. For example, as shown in FIG. 19, semiconductor laser light emitting device 5 may be of a TO-CAN package type.

As shown in FIG. 19, semiconductor laser light emitting device 5 according to a variation includes: base 510 made of metal, which is an example of a mounting base; cap 520 made of metal; and light-transmissive component 530 attached to cap 520. Cap 520 contains submount 20 and semiconductor laser 30. Base 510 includes stem base 511 and stem post 512 that is in a semicylindrical shape and attached to stem base 511. Examples of a material included in stem base 511 and stem post 512 include Cu.

Submount 20 on which semiconductor laser 30 is mounted is supported by base 510. Specifically, submount 20 on which semiconductor laser 30 is mounted is attached to stem post 512.

As with above-described Embodiment 1, stem post 512 includes step 11. Specifically, stem post 512 includes protruding portion 12, and protruding portion 12 forms step 11.

It should be noted that a pair of lead pins 61 and 62 are provided on stem base 511. Although not shown in the figure, the pair of lead pins 61 and 62 are electrically connected to a pair of electrodes of semiconductor laser 30 with gold wires.

Semiconductor laser light emitting device 5 thus configured achieves the same advantageous effects as above-described Embodiment 1.

It should be noted that it is possible to apply, to the present variation, the configurations of above-described Embodiments 1, 2, 3, and 4 and the variations thereof.

Moreover, although semiconductor laser 30 protrudes from front face 20a of submount 20 in each of the above-described embodiments, the present disclosure is not limited to this example. Semiconductor laser 30 need not protrude from front face 20a of submount 20. For example, front end face 30a of semiconductor laser 30 may be located at the same position as front face 20a of submount 20 or may be located posterior to front face 20a of submount 20.

Forms that can be obtained by various modifications to the respective embodiments and the respective variations thereof that can be conceived by a person skilled in the art, and forms obtained by arbitrarily combining the constituent elements and functions in the respective embodiments and the respective variations thereof without departing from the essence of the present disclosure are included in the present disclosure.

### INDUSTRIAL APPLICABILITY

The semiconductor laser light emitting device according to the present disclosure is useful as a light source in a product in a variety of fields such as an image display device such as a projector, an automobile component such as an in-vehicle headlamp, a lighting apparatus such as a spotlight, or industrial equipment such as laser processing equipment, and in particular as a light source in a device demanding a relatively high optical output.

1. A semiconductor laser light emitting device comprising:
a mounting base including a step;
a submount disposed above a bottom face of the step; and
a semiconductor laser disposed on the submount,
wherein a first lateral face of the step and a front face of the submount are in thermal contact with each other, the front face of the submount being a face of the submount on a light-emission direction side of the semiconductor laser.

2. The semiconductor laser light emitting device according to claim 1,
wherein a front end face of the semiconductor laser is located on the light-emission direction side of the semiconductor laser from the front face of the submount.

3. The semiconductor laser light emitting device according to claim 1,
wherein a position of a top edge of the first lateral face of the step is at a same height as or lower than a position of a top edge of the front face of the submount.

4. The semiconductor laser light emitting device according to claim 3,
wherein a distance from a bottom face of the submount to the top edge of the first lateral face of the step is at least 40% and at most 100% of a distance from the bottom face of the submount to a top face of the submount.

5. The semiconductor laser light emitting device according to claim 1,
wherein a top face of the step becomes lower with distance from the submount.

6. The semiconductor laser light emitting device according to claim 5,
wherein an angle formed by the top face of the step and a top face of the submount is at most 45°.

7. The semiconductor laser light emitting device according to claim 5,
wherein an angle formed by the top face of the step and a top face of the submount is less than or equal to half of a beam spread angle in a vertical direction of light emitted from the semiconductor laser.

8. The semiconductor laser light emitting device according to claim 1,
wherein the first lateral face of the step and the front face of the submount are parallel to each other.

9. The semiconductor laser light emitting device according to claim 1,
wherein the first lateral face and the bottom face of the step are perpendicular to each other.

10. The semiconductor laser light emitting device according to claim 1,
wherein the mounting base includes a first component and a second component that differ in material, and
the step is provided by disposing the second component on the first component.

11. The semiconductor laser light emitting device according to claim 10,
wherein the second component has a thermal conductivity higher than or equal to a thermal conductivity of the submount.

12. The semiconductor laser light emitting device according to claim 10,
wherein the second component has a thermal conductivity of at least 150 [W/(m/K)].

13. The semiconductor laser light emitting device according to claim 1,
wherein a second lateral face of the step and a lateral face of the submount are further in thermal contact with each other, the second lateral face being an other lateral face of the step and different from the first lateral face.

14. The semiconductor laser light emitting device according to claim 13,
wherein the mounting base is spaced apart from a corner at which the front face and the lateral face of the submount intersect.

15. The semiconductor laser light emitting device according to claim 1,
wherein a curved portion is provided in a base portion of the first lateral face of the step,
a groove that is dug into the mounting base is provided along the first lateral face of the step,
a bottom face of the groove is located lower than a mounting face of the mounting base on which the submount is mounted, and
a depth of the groove is greater than or equal to a height of the curved portion.

16. The semiconductor laser light emitting device according to claim 1,
wherein the mounting base is spaced apart from a corner at which the front face and a bottom face of the submount intersect.

17. The semiconductor laser light emitting device according to claim 1, further comprising:
a spacer disposed between the submount and the mounting base,
wherein a curved portion is provided in a base portion of the first lateral face of the step,
a front face of the spacer is spaced apart from the first lateral face of the step by at least an amount equal to a width of the curved portion, the front face of the spacer being a face of the spacer on the light-emission direction side of the semiconductor laser, and
the spacer has a thickness that is greater than or equal to the width of the curved portion.

18. The semiconductor laser light emitting device according to claim 1, further comprising:
a mirror that reflects light emitted from the semiconductor laser,
wherein the mounting base includes a third lateral face parallel to the first lateral face of the step, and
the mirror is in contact with the third lateral face.

19. The semiconductor laser light emitting device according to claim 1,
wherein the submount comprises a plurality of submounts, and the semiconductor laser comprises a plurality of semiconductor lasers,
each of the plurality of semiconductor lasers is disposed on a different one of the plurality of submounts, and
the first lateral face of the step and the front face of each of the plurality of submounts are in thermal contact with each other.

20. The semiconductor laser light emitting device according to claim 19, further comprising:
a plurality of mirrors each of which corresponds to a different one of the plurality of semiconductor lasers,
wherein the mounting base includes a third lateral face parallel to the first lateral face of the step, and
each of the plurality of mirrors is in contact with the third lateral face.

21. The semiconductor laser light emitting device according to claim 19,
wherein each of a plurality of second lateral faces of the step and a different one of lateral faces of the plurality of submounts are in thermal contact with each other, the plurality of second lateral faces being other lateral faces of the step and different from the first lateral face.
